(19) United States
(12) Patent Application Publication
(10) Pub. No.: US 2016/0043196 A1
(43) Pub. Date: Feb. 11, 2016

(54) SEMICONDUCTOR DEVICE

(71) Applicant: KABUSHIKI KAISHA TOSHIBA, Tokyo (JP)

(72) Inventors: Takeshi MURATA, Yokkaichi Mie (JP); Nobuhito KUGE, Yokkaichi Mie (JP)

(21) Appl. No.: 14/624,541

(22) Filed: Feb. 17, 2015

Related U.S. Application Data
(60) Provisional application No. 62/034,534, filed on Aug. 7, 2014.

(51) Int. Cl. H01L 29/49; H01L 27/115; H01L 29/66; H01L 29/788

(52) U.S. Cl. CPC H01L 29/4941; H01L 29/788; H01L 27/11524; H01L 29/665

(57) ABSTRACT

According to an embodiment, a semiconductor device includes a semiconductor element that is formed on a semiconductor substrate, an interlayer insulating film, including a silicon oxide film, that is formed to cover the semiconductor element, a wiring layer, including a metal, that is formed in the interlayer insulating film, and a first metal silicide film that is formed between the wiring layer and the interlayer insulating film.

### FIELD

Embodiments described herein relate to a semiconductor device.

### BACKGROUND

In a semiconductor device, various types of elements are formed on a semiconductor substrate. An interlayer insulating film is formed to cover the elements, and wiring layers are formed in the interlayer insulating film. A metal material may be used for the wiring layer, and a barrier metal film is interposed between the metal wiring layer and another conductive element (for example, a silicon substrate) so that an unnecessary reaction does not occur when the metal wiring layer is connected to the conductive element. When the barrier metal film comes into contact with an interlayer insulating film formed of a silicon oxide film, the possibility of the barrier metal film corroding increases.

### DESCRIPTION OF THE DRAWINGS

FIG. 1 is an example of a schematic diagram illustrating an electrical configuration of a portion of a memory cell region and peripheral circuit region of a nonvolatile semiconductor memory device according to a first embodiment.

FIG. 2 is an example of a schematic plan view of the memory cell region according to the first embodiment.

FIG. 3 is an example of a schematic plan view of a transistor in the peripheral circuit region according to the first embodiment.

FIG. 4A is an example of a schematic longitudinal sectional view of a portion of the device taken along line 4A-4A in FIG. 2 according to the first embodiment.

FIG. 4B is an example of a schematic longitudinal sectional view of a portion of the device taken along line 4B-4B in FIG. 2 according to the first embodiment.

FIG. 4C is an example of a schematic longitudinal sectional view of a portion of the device taken along line 4C-4C in FIG. 3 according to the first embodiment.

FIGS. 5A, 6A, 7A, 8A, 9A, 10A, 11A, 12A, 13A, 14A, 15A, 16A, and 17A are examples of a schematic longitudinal sectional view illustrating one step of a manufacturing process of the portion of the device taken along line 4A-4A in FIG. 2 according to the first embodiment.

FIGS. 5B, 6B, 7B, 8B, 9B, 10B, 11B, 12B, 13B, 14B, 15B, 16B, and 17B are examples of a schematic longitudinal sectional view illustrating one step of a manufacturing process of the portion of the device taken along line 4B-4B in FIG. 2 according to the first embodiment.

FIGS. 5C, 6C, 7C, 8C, 9C, 10C, 11C, 12C, 13C, 14C, 15C, 16C, and 17C are examples of a schematic longitudinal sectional view illustrating one step of a manufacturing process of the portion of the device taken along line 4C-4C in FIG. 3 according to the first embodiment.

FIG. 18A is an example of a schematic longitudinal sectional view illustrating a portion of the device taken along line 4A-4A in FIG. 2 according to a second embodiment.

FIG. 18B is an example of a schematic longitudinal sectional view illustrating a portion of the device taken along line 4B-4B in FIG. 2 according to the second embodiment.

FIG. 18C is an example of a schematic longitudinal sectional view illustrating a portion of the device taken along line 4C-4C in FIG. 3 according to the second embodiment.

FIG. 19A is an example of a schematic longitudinal sectional view illustrating a portion of the device taken along line 4A-4A in FIG. 2 according to a third embodiment.

FIG. 19B is an example of a schematic longitudinal sectional view illustrating a portion of the device taken along line 4B-4B in FIG. 2 according to the third embodiment.

FIG. 19C is an example of a schematic longitudinal sectional view illustrating a portion of the device taken along line 4C-4C in FIG. 3 according to the third embodiment.

FIGS. 20A and 21A are examples of a schematic longitudinal sectional view illustrating one step of a manufacturing process of the portion of the device taken along line 4A-4A in FIG. 2 according to the third embodiment.

FIGS. 20B and 21B are examples of a schematic longitudinal sectional view illustrating one step of a manufacturing process of the portion of the device taken along line 4B-4B in FIG. 2 according to the third embodiment.

FIGS. 20C and 21C are examples of a schematic longitudinal sectional view illustrating one step of a manufacturing process of the portion of the device taken along line 4C-4C in FIG. 3 according to the third embodiment.

FIG. 22A is an example of a schematic longitudinal sectional view of a portion of the device taken along line 4A-4A in FIG. 2 according to a fourth embodiment.

FIG. 22B is an example of a schematic longitudinal sectional view of a portion of the device taken along line 4B-4B in FIG. 2 according to the fourth embodiment.

FIG. 22C is an example of a schematic longitudinal sectional view of a portion of the device taken along line 4C-4C in FIG. 3 according to the fourth embodiment.

FIG. 23A is an example of a schematic longitudinal sectional view of a portion of the device taken along line 4A-4A in FIG. 2 according to a fifth embodiment.

FIG. 23B is an example of a schematic longitudinal sectional view of a portion of the device taken along line 4B-4B in FIG. 2 according to the fifth embodiment.

FIG. 23C is an example of a schematic longitudinal sectional view of a portion of the device taken along line 4C-4C in FIG. 3 according to the fifth embodiment.

### DETAILED DESCRIPTION

According to an embodiment, a semiconductor device includes a semiconductor element that is formed on a semiconductor substrate, an interlayer insulating film, including a silicon oxide film, that is formed to cover the semiconductor element, a wiring layer, including a metal, that is formed in the interlayer insulating film, and a first metal silicide film that is formed between the wiring layer and the interlayer insulating film.

Hereinafter, several embodiments will be described.

The same or similar components in the embodiments will be denoted by the same or similar reference numerals and symbols, and a repeated description thereof will be omitted when not necessary. A description will be given with a focus on characteristic portions of each embodiment.

### First Embodiment

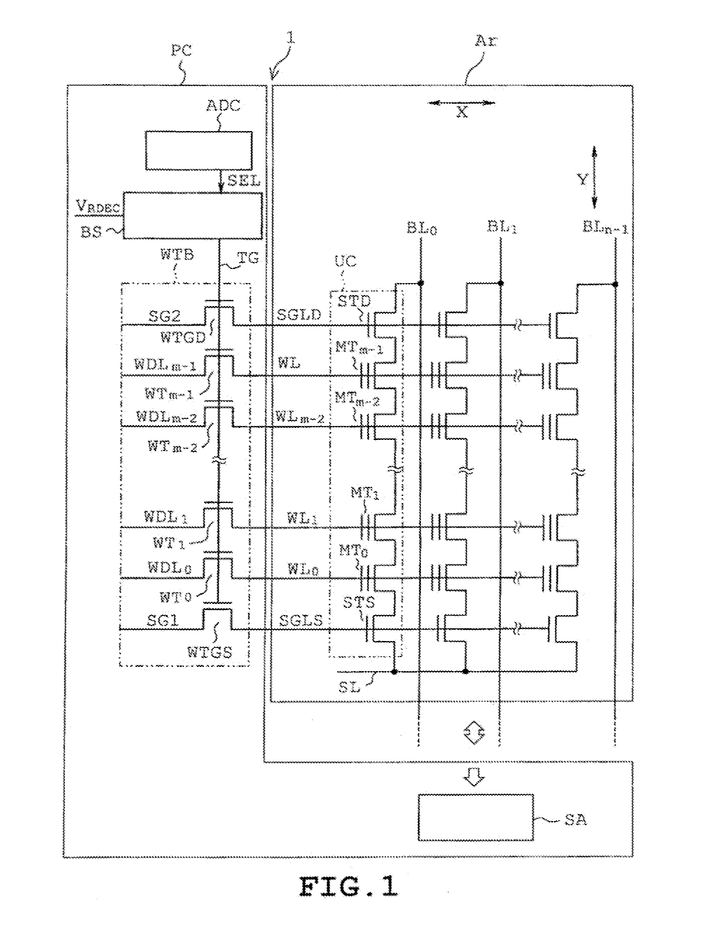

Hereinafter, reference will be made to FIG. 1 to FIGS. 17A to 17C to describe a first embodiment in which a semiconductor device is applied to a NAND type flash memory device. In addition, the drawings are schematically illustrated, and the relationship between thicknesses and planar sizes, the ratio of the thicknesses of each layer, and the like do not necessarily coincide with an actual device. In addition, vertical and horizontal directions indicate relative directions when a circuit formation surface side in a semiconductor substrate to be described later faces upwards, and do not necessarily coincide with directions based on a gravitational acceleration direction.

FIG. 1 is an example of a schematic block diagram illustrating an electrical configuration of a NAND type flash memory device. As illustrated in FIG. 1, a NAND type flash memory device 1 includes a memory cell array Ar in which a large number of memory cells are disposed in matrix form, and a peripheral circuit PC that reads, writes, and erases the memory cells of the memory cell array Ar.

A plurality of cell units UC are disposed in the memory cell array Ar within a memory cell region. The cell units UC include a selection transistor STD connected to a bit line BL side, a selection transistor STS connected to a source line SL side, and a plurality of (for example, 64 (=m)) memory cells (equivalent to semiconductor elements) MT, as semiconductor elements, which are connected to each other in series between the two selection transistors STD and STS. Meanwhile, one or a plurality of dummy transistors may be provided between the selection transistor STD and the memory cell MT adjacent to the selection transistor STD, and a dummy transistor may be provided between the selection transistor STS and the memory cell MT adjacent to the selection transistor STS.

One block has n columns of cell units UC which are arrayed in parallel in an X direction (horizontal direction in FIG. 1). The memory cell array Ar has a plurality of blocks arrayed in a Y direction (vertical direction in FIG. 1). In addition, FIG. 1 illustrates only one block for the purpose of simplifying a description.

A peripheral circuit region is provided in the vicinity of the memory cell region, and the peripheral circuit PC is disposed in the vicinity of the memory cell array Ar. The peripheral circuit PC includes an address decoder ADC, a sense amplifier SA, a booster circuit BS including a charge pump circuit, a transfer transistor unit WTB, and the like. The address decoder ADC is electrically connected to the transfer transistor unit WTB through the booster circuit BS.

The address decoder ADC selects one block in response to an address signal applied from the outside. The booster circuit BS boosts a driving voltage which is supplied from the outside when a selection signal of a block is applied, and supplies a predetermined voltage to the transfer gate transistors WTGD, WTGS, and WT through a transfer gate line TG.

The transfer transistor unit WTB includes a transfer gate transistor WTGD, a transfer gate transistor WTGS, a word line transfer gate transistors WT, and the like. The transfer transistor unit WTB is provided corresponding to each block.

One of the drain and the source of the transfer gate transistor WTGD is connected to a selection gate driver line SG2, and the other is connected to a selection gate line SGLD. One of the drain and the source of the transfer gate transistor WIGS is connected to a selection gate driver line SG1, and the other is connected to a selection gate line SGLS. One of the drain and the source of the transfer gate transistor WT is connected to a word line driving signal line WDL, and the other is connected to the word line WL provided within the memory cell array Ar.

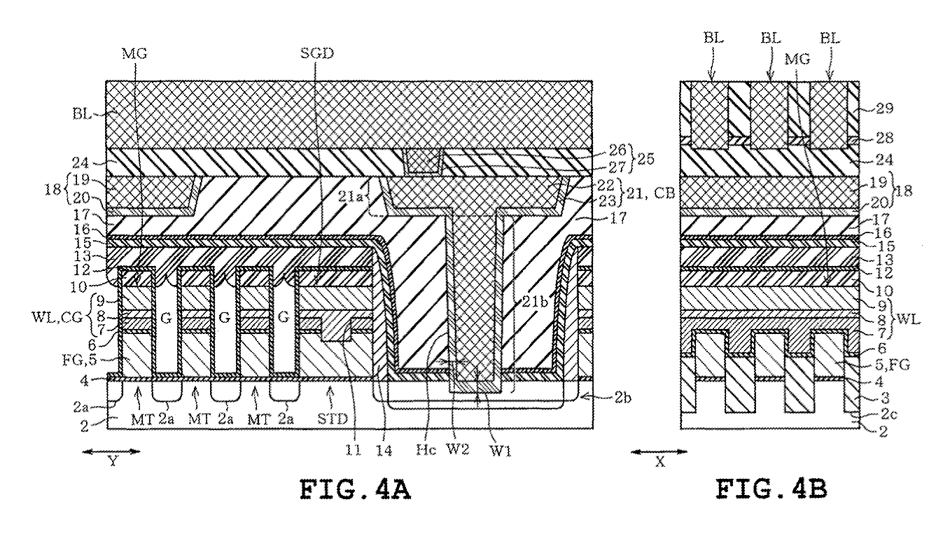

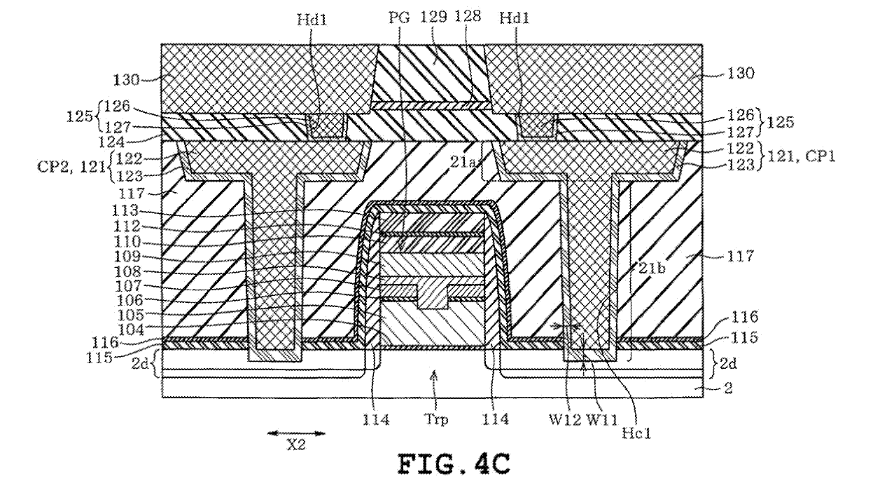

In the plurality of cell units UC arrayed in the X direction, gates (SGD of FIG. 4A) of the respective selection transistors STD are electrically connected to each other by the selection gate line SGLD. Gate electrodes of the respective selection transistors STS are electrically connected to each other by the selection gate line SGLS. Sources of the respective selection transistors STS are connected in common to the source line SL. In the memory cells MT of the plurality of cell units UC arrayed in the X direction, the gate electrodes (MG of FIG. 4A) thereof are electrically connected to each other by the word line WL.

In the transfer gate transistors WTGD, WIGS, and WT, the gate electrodes thereof are connected to each other in common by the transfer gate line TG, and are connected to a boosting voltage supply terminal of the booster circuit BS. The sense amplifier SA is connected to the bit lines BL, and is connected to a latch circuit that temporarily stores data at the time of reading out the data.

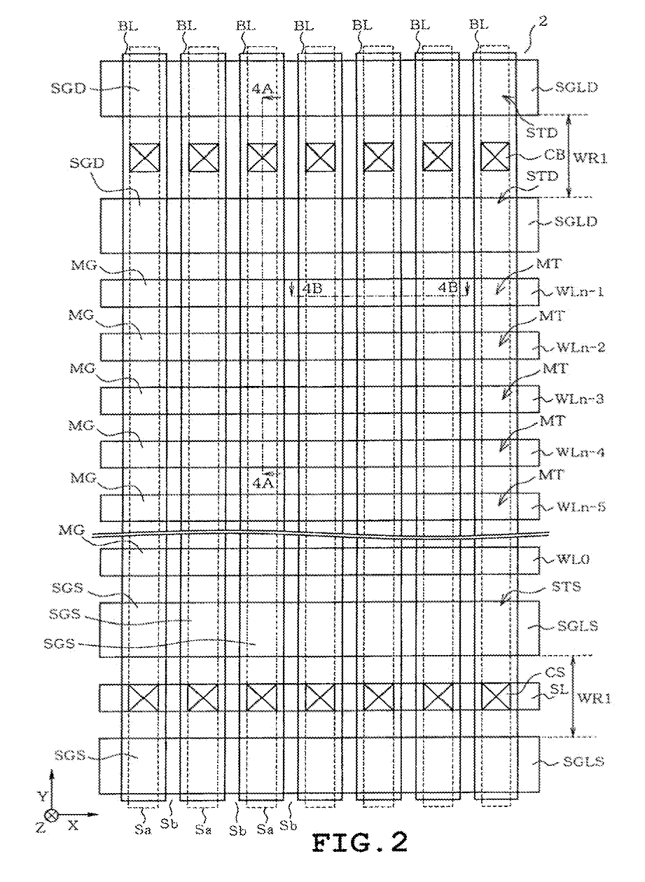

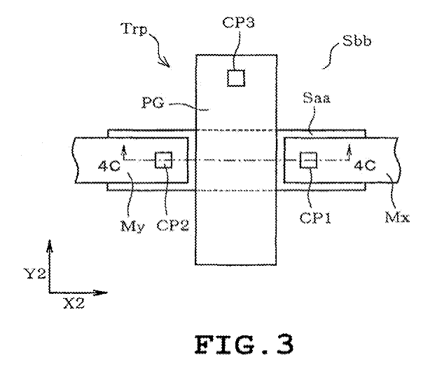

FIG. 2 illustrates an example of a layout pattern of a portion of a memory cell region, and FIG. 3 illustrates an example of a layout pattern of a portion of a peripheral circuit region. The peripheral circuit PC and the memory cell array Ar are formed on the semiconductor substrate 2. The semiconductor substrate 2 is formed of, for example, a p-type single crystal silicon substrate.

As illustrated in FIG. 2, in a memory cell region of the semiconductor substrate 2, element isolation areas Sb are formed to extend along the Y direction in FIG. 2. The element isolation areas Sb are configured such that an insulating film (reference numeral 3 of FIG. 4B) is embedded in a trench formed along the Y direction, and is formed to have a so-called shallow trench isolation (STI) structure.

The plurality of element isolation areas Sb are formed in the X direction in FIG. 2 at predetermined intervals. Thus, element regions Sa are formed to extend in the Y direction of FIG. 2, and a plurality of element regions Sa are formed in a surface portion of the semiconductor substrate 2 to be separated from each other in the X direction.

The word lines WL are formed to extend along a direction (X direction in FIG. 2) perpendicular to and cross the element regions Sa. The plurality of word lines WL are formed in the Y direction in FIG. 2 at predetermined intervals. The gate electrode MG of the memory cell (memory cell transistor) MT is formed on the element region Sa crossing the word line WL.

The plurality of memory cells MT, which are adjacent and connected to each other in series in the Y direction, configure a NAND string. A selection transistor STD is formed adjacent to each of both outer sides of the memory cells MT at both ends of the NAND string in the Y direction. The plurality of selection transistors STD are provided in the X direction, and the gate electrodes SGD of the plurality of selection transistors STD are electrically connected to each other through the selection gate line SGLD. Meanwhile, the gate electrode SGD of the selection transistor STD is formed on the element region Sa crossing the selection gate line SGLD.

A bit line contact electrode CB is formed on the element region Sa between the selection transistors STD of two adjacent blocks. The bit line contact electrode CB is a contact electrode that electrically connects the bit line BL formed on the element region Sa to extend in the Y direction and the element region Sa of the semiconductor substrate 2.

FIG. 3 illustrates an example of a layout of a transistor Trp in a peripheral circuit region. The semiconductor substrate 2 is provided with an element isolation area Sbb in the peripheral circuit region. The element isolation area Sbb is configured such that a trench is formed in the vicinity of a rectangular element region Saa to leave the rectangular element region and that an insulating film (not illustrated) is embedded in the trench. The element isolation area Sbb is formed to have a so-called shallow trench isolation (STI) structure.

The transistor Trp is formed of the element region Saa having a rectangular shape in an X2 direction and a Y2 direction, and includes a gate electrode PG which is formed to cross above the element region Saa in a certain predetermined direction (Y2 direction in FIG. 3). That is, the gate electrode PG is formed to protrude from the element region Saa in the Y2 direction and to reach the element isolation area Sbb.

The transistor Trp includes source and drain regions (see 2d of FIG. 4C) which are formed by diffusing, for example, n-type impurities into the element regions Saa on either side of the gate electrode PG. Contact electrodes CP1 and CP2 are formed respectively on the element regions Saa (source and drain region 2d) on either side of the gate electrode PG. The contact electrodes CP1 and CP2 connect the element region Saa (source and drain region 2d) and wirings Mx and My located on an upper layer. In addition, a contact electrode CP3 is formed in contact with the gate electrode PG, but is disposed on the element isolation area Sbb on the outer side of the element region Saa when seen in a plan view.

FIGS. 4A and 4B are examples illustrating schematic cross-sectional structures of the selection transistor STD and the memory cell MT formed in the memory cell region. FIG. 4C is an example illustrating a schematic cross-sectional structure of the transistor Trp formed in the peripheral circuit region. FIG. 4A illustrates an example of a schematic longitudinal sectional view of a portion taken along line 4A-4A of FIG. 2, and FIG. 4B illustrates an example of a schematic longitudinal sectional view of a portion taken along line 4B-4B of FIG. 2. FIG. 4C illustrates an example of a schematic longitudinal sectional view of a portion taken along line 4C-4C of FIG. 3. Meanwhile, FIGS. 4A, 4B and FIG. 4C illustrate a state after the gate electrodes MG, SGD, and PG of the memory cell MT, the selection transistor STD, and the transistor Trp are subjected to separation processing.

In the cross-section of the memory cell region illustrated in FIG. 4B, device isolation grooves 2c are formed in the semiconductor substrate 2, and an element isolation film 3 is embedded in the trench 2c. The element isolation film 3 is formed of an insulating film (for example, a silicon oxide film). The element isolation film 3 is formed to protrude upwardly from the top surface of the semiconductor substrate 2. The plurality of element isolation films 3 are formed in the X direction to be separated from each other. A gate insulating film 4 is formed on the top surface of the semiconductor substrate 2 between the adjacent element isolation films 3. The gate insulating film 4 is formed of, for example, a silicon oxide film. The gate electrodes MG of the memory cells MT are formed on the upper surface of the gate insulating film 4. The gate electrode MG is configured such that a polysilicon film 5, an interelectrode insulating film 6, a polysilicon film 7, a polysilicon film 8, and a tungsten (W) film 9 are sequentially stacked on the gate insulating film 4 and that a silicon nitride film 10 is stacked on the tungsten film 9 as a cap film.

In a cross-section illustrated in FIG. 4B, the polysilicon film 5 is formed to protrude upwardly from the position of the top surface of the element isolation film 3. In addition, the interelectrode insulating film 6 is formed along the top surface of the element isolation film 3 and the upper side surface and the top surface of the polysilicon film 5.

Similarly to the example of the cross-section of the memory cell region illustrated in FIG. 4A, the gate insulating film 4 is formed on the top surface of the semiconductor substrate 2. The gate electrodes MG of the plurality of memory cells MT and the selection gate electrode SGD of the selection transistor STD for selecting a memory cell MT are formed on the top surface of the gate insulating film 4. Although not illustrated in the drawing, a selection gate electrode SGS of the selection transistor STS for selecting the memory cell MT is also formed thereon.

The memory cell MT includes the gate electrode MG and a source and drain region 2a formed in the surface layer of the semiconductor substrate 2 on either side of the gate electrode MG in the Y direction. The plurality of memory cells MT are formed adjacent to each other in the Y direction.

As described above, the gate electrode MG of the memory cell MT is configured such that the polysilicon film 5, the interelectrode insulating film 6, the polysilicon film 7, the polysilicon film 8, and the tungsten (W) film 9 are sequentially stacked on the gate insulating film 4 and that the silicon nitride film 10 is stacked on the tungsten film 9 as a cap film.

The polysilicon film 5 is formed of a p-type film by being doped with, for example, p-type impurities (for example, boron (B)), and is formed as an electrode film. The polysilicon film 5 is configured as a floating electrode FG within the memory cell MT. For example, similarly to the polysilicon film 5, the polysilicon films 7 and 8 are formed of a p-type film by being doped with p-type impurities (for example, boron (B)), and are formed as electrode films. Meanwhile, a configuration is illustrated in which a polysilicon film having p-type impurities introduced thereto is used as the polysilicon film 7. However, a polysilicon film having n-type impurities (for example, phosphorus (P)) introduced thereto may be used, and the embodiment is not limited thereto. The tungsten film 9 is configured such that a so-called barrier metal film (not illustrated) is formed on the bottom surface thereof, and is formed as a metal film. The polysilicon films 7 and 8 and the tungsten film 9 are configured as control electrodes CG and the word line WL.

The interelectrode insulating film 6 is formed using, for example, an oxide-nitride-oxide (ONO) film, a nitride-oxide-nitride-oxide-nitride (NONON) film, or a film in which a nitride film located at an intermediate position of the ONO film or the NONON film is replaced with an insulating film having a high dielectric constant characteristic.

As illustrated in FIG. 4A, in the surface portion of the semiconductor substrate 2, the source and drain regions 2a are provided between the gate electrodes MG and MG and between the gate electrodes SGD and MG, and a drain region 2b is provided between the gate electrodes SGD and SGD (equivalent to below the bit line contact electrode CB of FIG. 2).

The gate electrode SGD of the selection transistor STD is formed to have substantially the same structure as that of the gate electrode MG of the memory cell MT. The gate electrode SGD has a configuration in which the polysilicon film 5, the interelectrode insulating film 6, the polysilicon films 7 and 8, and the tungsten film 9 are sequentially stacked on the gate insulating film 4. The silicon nitride film 10 is further stacked on the tungsten film 9.

The gate electrode SGD is configured such that an opening 11 is formed in the center portion of the polysilicon film 7 and the interelectrode insulating film 6, and the polysilicon film 8 is embedded in the opening 11, and thus the polysilicon films 5 and 8 come into contact with each other and are electrically connected to each other.

As illustrated in FIGS. 4A and 4B, a protective film 12 is formed conformally on the side surfaces of the gate electrodes MG and SGD and the side surface and the top surface of the silicon nitride film 10. The protective film 12 is formed of, for example, a silicon oxide film.

A gap G is provided between the gate electrodes MG and MG and between the gate electrodes MG and SGD. The gap G is provided in order to suppress inter-cell interference between the gate electrodes MG and MG and between the gate electrodes MG and SGD. An insulating film 13 for forming the gap G is formed on the silicon nitride films 10 on the gate electrodes MG and SGD. The insulating films 13, formed of, for example, a silicon oxide film, are formed to communicate with each other in the Y direction.

In FIG. 4A, one side surface of the selection gate electrode SGD in the Y direction is formed to be flush with the side surface of the insulating film 13 and the side surface of the silicon nitride film 10 on the selection gate electrode SGD. A spacer film 14 is formed on one side surface of each of the selection gate electrode SGD, the silicon nitride film 10, and the insulating film 13 in the Y direction.

A silicon oxide film 15 is formed over the top surface of the insulating film 13 and the top surface and the side surface of the spacer film 14. A silicon nitride film 16 is formed over the silicon oxide film 15 to cover the silicon oxide film 15.

An interlayer insulating film 17 is formed on the silicon nitride film 16. The interlayer insulating film 17 is formed of, for example, a silicon oxide film. A wiring portion 18 is formed in the interlayer insulating film 17 on the upper side of the memory cell MT. The wiring portion 18 includes a wiring layer 19 including a metal, and a metal silicide film (first metal silicide film) 20 which is formed along the entirety of the side surface and the bottom surface of the wiring layer 19. The wiring layer 19, formed of, for example, a tungsten (W) film, is a wiring layer which is provided in order to link other conductive elements not illustrated in the drawing. The metal silicide film 20 is formed to be interposed between the wiring layer 19 and the interlayer insulating film 17.

The metal silicide film 20 is formed of, for example, titanium silicide (TiSi). The metal silicide film 20 is formed along the entirety of the bottom surface and the side surface of the wiring layer 19. The metal silicide film 20 is formed by silicifying and denaturing, for example, titanium (Ti) used as a material of a barrier metal. The metal silicide film 20 is formed along the entirety of the bottom surface and the side surface of the wiring layer 19 in order to prevent titanium (Ti) used as a barrier metal from directly coming into contact with the interlayer insulating film 17.

A hole Hc is formed in the interlayer insulating film 17, the silicon nitride film 16, and the silicon oxide film 15 to reach an upper portion of the semiconductor substrate 2. A wiring layer 21 is formed within the hole Hc. A description will be given below based on a shape. The wiring layer 21 includes a wiring portion 21a, having a large width in the Y direction, which is formed to have the same height as that of the wiring portion 18 and is formed in the same layer as the wiring portion 18, and a contact portion 21b, having a small width, which connects a portion of a lower portion of the wiring portion 21a and the upper portion of the semiconductor substrate 2. The wiring portion 21a and the contact portion 21b are integrally formed. In addition, the wiring portion 21a is located above the memory cell MT and is formed in an upper portion of the interlayer insulating film 17. A description will be given below based on a film forming material. The wiring layer 21 includes a wiring layer 22 including a metal, and a metal silicide film 23 which is formed along the side surface and bottom surface of the wiring layer 22. The wiring layer 22 is formed of a metal (for example, tungsten (W)), and is configured as a portion of a contact electrode for linking the semiconductor substrate 2 and a wiring portion 25 (to be described later) which is located at an upper layer. The metal silicide film 23 is formed along the bottom surface and side surface of the wiring layer 22, and is configured as a portion of a contact electrode for linking the semiconductor substrate 2 and the wiring portion 25 (to be described later) which is located at an upper layer.

The metal silicide film 23 is formed by silicifying and denaturing a metal (for example, titanium (Ti)) and is formed of, for example, titanium silicide (TiSi). The metal silicide film 23 is formed along the bottom surface and side surface of the wiring layer 22 in order to prevent the metal (for example, titanium (Ti)) from corroding, as much as possible, due to the direct contact with the interlayer insulating film 17. In the bottom surface of the hole Hc, a silicidation film thickness W1 of the metal silicide film 23 is larger than a silicidation film thickness W2 of the side surface thereof.

An interlayer insulating film 24 is formed on the interlayer insulating film 17 and the wiring portions 18 and 21. The interlayer insulating film 24 is formed of, for example, a silicon oxide film. A hole Hd is formed in the interlayer insulating film 24. A wiring portion 25 is formed within the hole Hd. The wiring portion 25 includes a wiring layer 26 and a barrier metal film 27. The wiring layer 26 is formed of a metal (for example, tungsten (W)), and is configured as a portion of a via plug for linking the wiring layer 21 and the bit line BL which is located at an upper layer. For example, the barrier metal film 27 is formed along the bottom surface and side surface of the wiring layer 26 and is formed of, for example, titanium nitride (TiN). The top surfaces of the wiring portion 25 and the interlayer insulating film 24 are formed flush with each other.

As illustrated in FIG. 4B, a barrier film 28 is formed on the interlayer insulating film 24. The barrier film 28 is formed of, for example, a silicon nitride film. An interlayer insulating film 29 is formed on the barrier film 28. The interlayer insulating film 29 is formed of, for example, a silicon oxide film. Grooves are formed through the interlayer insulating film 29, the barrier film 28, and the interlayer insulating film 24 in the Y direction to be separated from each other in the X direction. The structure of the bit line BL is formed within the grooves. The bit line BL is formed of a metal (for example, copper (Cu) or tungsten (W)). Therefore, in the cross-section illustrated in FIG. 4A, the structure of the bit line BL is formed on the interlayer insulating film 24 and the wiring portion 25.

Next, the structure of the transistor Trp in the peripheral circuit region will be described with reference to FIG. 4C. The stacked structure of the transistor Trp on the semiconductor substrate 2 in the peripheral circuit region is a stacked structure which is substantially the same as the structure of the selection transistor STD mentioned above. Meanwhile, for convenience of description, in FIG. 4C illustrating the structure within the peripheral circuit region, films manufactured using the same main material in the same manufacturing process as in the memory cell region illustrated in FIGS. 4A and 4B or in the previous or subsequent manufacturing process are denoted by reference numerals 114 to 129 by adding 100 to the components 4 to 29 illustrated in FIGS. 4A and 4B. Therefore, the films have different reference numerals, but represent films formed of the same main material.

As illustrated in FIG. 3, the semiconductor substrate 2 is processed in the peripheral region of the transistor Trp, and the element region Saa has a structure in which the vicinity thereof is surrounded by the element isolation area Sbb. In a region where the transistor Trp is formed, a gate insulating film 104 is formed on the top surface of the semiconductor substrate 2. Since the breakdown voltage of the gate insulating film 104 varies according to the type of the transistor Trp, the gate insulating film is formed to have a larger film thickness in a transistor having a breakdown voltage which is higher than a predetermined value.

The gate electrode PG is formed on the gate insulating film 104. The gate electrode PG is configured such that a polysilicon film 105, an interelectrode insulating film 106, a polysilicon film 107, a polysilicon film 108, and a tungsten (W) film 109 are sequentially stacked on the gate insulating film 104 and that a silicon nitride film 110 is stacked on the tungsten film 109 as a cap film.

The polysilicon film 105 is formed of an n-type film by being doped with, for example, n-type impurities (for example, phosphorus (P)), and is formed as an electrode film. The polysilicon films 107 and 108 are formed of n-type films by being doped with, for example, n-type impurities (for example, phosphorus (P)), and are formed as electrode films. Meanwhile, a configuration is illustrated in which a polysilicon film having n-type impurities introduced thereto is used as the polysilicon films 105, 107, and 108. However, a polysilicon film having p-type impurities (for example, boron (B)) introduced thereto may be used, and the embodiment is not limited thereto.

The interelectrode insulating film 106 is formed using, for example, an oxide-nitride-oxide (ONO) film, a nitride-oxide-nitride-oxide-nitride (NONON) film, or a film in which a nitride film located at an intermediate position of the ONO film or the NONON film is replaced with an insulating film having a high dielectric constant characteristic.

The gate electrode PG is configured such that an opening is formed in the center of the polysilicon film 107 and the interelectrode insulating film 106 and that a concave portion is formed in the center of an upper portion of the polysilicon film 105. The polysilicon film 108 is embedded in the openings and into the concave portion, and the tungsten film 109 and the silicon nitride film 110 are formed on the polysilicon film 108.

A protective film 112 is formed on the top surface of the silicon nitride film 110, and an insulating film 113 is formed on the protective film 112. Side surfaces of the gate insulating film 104, the polysilicon film 105, the interelectrode insulating film 106, the polysilicon films 107 and 108, the tungsten film 109, the silicon nitride film 110, the protective film 112, and the insulating film 113 in the X2 direction are formed flush with each other.

A spacer film 114 is formed on the side surfaces of the gate insulating film 104, the polysilicon film 105, the interelectrode insulating film 106, the polysilicon films 107 and 108, the tungsten film 109, the silicon nitride film 110, the protective film 112, and the insulating film 113 in the X2 direction.

A silicon oxide film 115 is formed on the top surface of the insulating film 113 and the top surface and the side surface of the spacer film 114, and a silicon nitride film 116 is formed on the silicon oxide film 115 to cover the silicon oxide film 115.

An interlayer insulating film 117 is formed on the silicon nitride film 116. A hole Hc1 is formed through the interlayer insulating film 117, the silicon nitride film 116, and the silicon oxide film 115 to reach the upper portion of the semiconductor substrate 2. The holes Hc1 are formed respectively on either side of the gate electrode PG in the X2 direction at an interval to reach the upper portion of the semiconductor substrate 2. A wiring portion 121 is formed within the hole Hc1. A description will be given below based on a shape. The wiring portion 121 includes a wiring portion 121a, having a large width, which is formed to have the same height as those of the wiring portions 18 and 21a and is formed in the same layer as the wiring portions, and a contact portion 121b, having a small width, which connects a portion of a lower portion of the wiring portion 121a and the upper portion of the semiconductor substrate 2.

In addition, the wiring portion 121a is formed to be located above the gate electrode PG. In addition, a description will be given below based on a film forming material. The wiring portion 121 includes a wiring layer 122 including a metal and a metal silicide film 123 which is formed along the side surface and bottom surface of the wiring layer 122. The wiring layer 122 is formed of a metal (for example, tungsten (W)), and is configured as a portion of a contact electrode for linking the semiconductor substrate 2 and the bit line BL which is located at an upper layer.

The metal silicide film 123 is formed along the bottom surface and side, surface of the wiring layer 122, and is configured as a portion of a contact electrode for linking the semiconductor substrate 2 and the bit line BL which is located at an upper layer.

The metal silicide film 123 is formed by siliciding and denaturing a metal (for example, titanium (Ti)) and is formed of, for example, titanium silicide (TiSi). The metal silicide film 123 is formed along the bottom surface and side surface of the wiring layer 122 in order to prevent the metal (for example, titanium (Ti)) from corroding due to the direct contact with the interlayer insulating film 117. In the bottom surface of the hole Hc, a silicidation film thickness W11 of the silicide film 123 is larger than a silicidation film thickness W12 of the side surface thereof.

An interlayer insulating film 124 is formed on the interlayer insulating film 117 and the wiring portion 121. The interlayer insulating film 124 is formed of, for example, a silicon oxide film. A hole Hd1 is formed in the interlayer insulating film 124. A wiring portion 125 is formed within the hole Hd1. The wiring portion 125 includes a wiring layer 126 and a barrier metal film 127. The wiring layer 126 is formed of a metal (for example, tungsten (W)), and is configured as a portion of a via plug for linking the wiring portion 121 and a wiring portion 130 (to be described later) which is located at an upper layer. The barrier metal film 127 is formed along the bottom surface and the side surface of the wiring layer 126 and is formed of, for example, titanium (Ti). The top surfaces of the wiring portion 125 and the interlayer insulating film 124 are formed flush with each other.

A barrier film 128 is formed on the interlayer insulating film 124. The barrier film 128 is formed of, for example, a silicon nitride film. An interlayer insulating film 129 is formed on the barrier film 128. The interlayer insulating film 129 is formed of, for example, a silicon oxide film. Grooves are formed in the interlayer insulating film 129, the barrier film 128, and the interlayer insulating film 124, and the wiring portion 130 is formed within the grooves. The wiring portion is formed of a metal (for example, copper (Cu) or tungsten (W)).

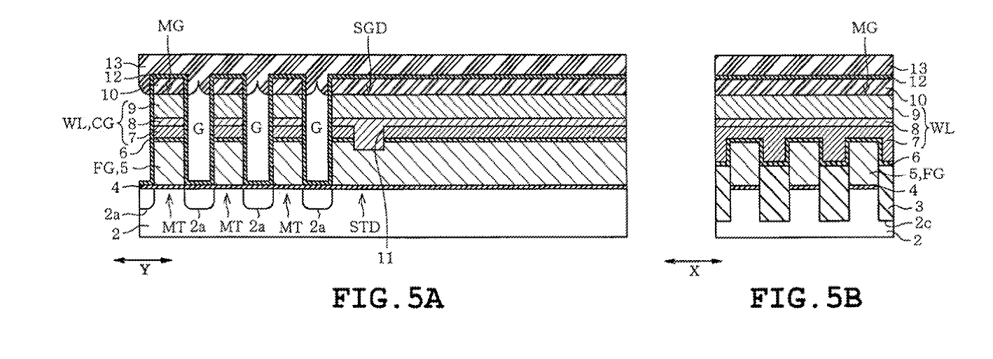

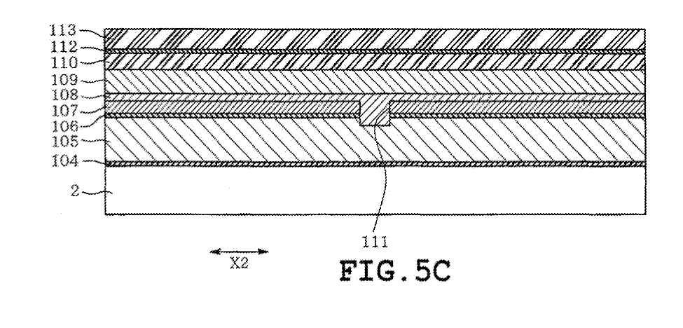

Next, an example of a manufacturing process for the structures illustrated in FIGS. 4A to 4C will be described with reference to FIGS. 5A to 17C. Meanwhile, a description will be given below with a focus on characteristic portions, but another process may be added between processes as long as the process is a general process, or the following processes may be deleted when necessary. In addition, the processes may be appropriately changed as long as the processes may be performed practically. Meanwhile, a manufacturing method up to the structures illustrated in FIGS. 5A to 5C will be schematically described.

First, a well region and the like are formed in the surface layer of the semiconductor substrate 2 by ion implantation (not illustrated), and the gate insulating films 4 and 104 having a predetermined film thickness are formed on the top surface of the semiconductor substrate 2. For example, a p-type single crystal silicon substrate is used as the semiconductor substrate 2. When, for example, a silicon oxide film is used as the gate insulating films 4 and 104, the gate insulating films may be formed using a thermal oxidation method based on, for example, dry O₂ treatment. Meanwhile, the gate insulating films 4 and 104 have different breakdown voltage characteristics, and may be individually formed when the thicknesses thereof are made different from each other.

Next, the polysilicon films 5 and 105 are deposited on the top surfaces of the gate insulating films 4 and 104, respectively, using, for example, a chemical vapor deposition (CVD) method. At this time, p-type impurities (for example, boron (B)) are introduced into the polysilicon film 5, and n-type impurities (for example, phosphorus (P)) are introduced into the polysilicon film 105. Next, a silicon nitride film and the like (not illustrated) for a hard mask are formed on the top surfaces of the polysilicon films 5 and 105, and the device isolation groove 2c is formed in the memory cell region by performing anisotropic etching of the polysilicon films 5 and 105, the gate insulating films 4 and 104, and the surface layer of the semiconductor substrate 2 (see FIG. 5B).

In the memory cell region, the element isolation film 3 is formed within the device isolation groove 2c using, for example, a CVD method or a coating method, thereby forming the element isolation area Sb. The element isolation film 3 is polished up to the position of the top surface of the silicon nitride film for a hard mask and is then planarized. The silicon nitride film is removed using hot phosphoric acid, and etch-back processing is selectively performed on the element isolation film 3 so that the top surface of the element isolation film 3 is positioned below the top surface of the polysilicon film 5 and above the top surface of the gate insulating film 4 (see FIG. 5B). Meanwhile, the element isolation areas Sbb in the peripheral circuit region are formed at substantially the same time. Thus, the element regions Saa may be defined in the semiconductor substrate 2, but are not illustrated in the drawing.

The interelectrode insulating films 6 and 106 are formed on the top surfaces and the side surfaces of the polysilicon films 5 and 105, respectively. The interelectrode insulating films 6 and 106 may be formed in the same process. For example, when an ONO film is formed as the interelectrode insulating film, the ONO film may be formed using, for example, a CVD method. Further, the polysilicon films 7 and 107 are formed to cover the element isolation film 3 and the respective interelectrode insulating films 6 and 106. The polysilicon films 7 and 107 may be formed in the same process.

The opening 11 and a concave portion 5a are formed in a region corresponding to a portion (for example, a central portion) of the gate electrode SGD of the selection transistor STD using a photolithography technique and an anisotropic etching technique. In addition, an opening 111 is formed in a region corresponding to a portion (for example, a central portion) of the gate electrode PG of the peripheral transistor Trp using a photolithography technique and an anisotropic etching technique.

In these processes, an opening is formed in a portion corresponding to a partial region of the selection gate electrode SGD in the memory cell region and in a portion corresponding to a partial region of the gate electrode PG in the peripheral circuit region by applying and patterning a resist (not illustrated). The openings 11 and 111 are formed by etching the polysilicon films 7 and 107 and the interelectrode insulating films 6 and 106, respectively, using, for example, a reactive ion etching (RIE) method. Further, the concave portions 5a and 105a are formed in the polysilicon films 5 and 105, respectively. Next, the polysilicon films 8 and 108 are deposited on the top surfaces of the polysilicon films 7 and 107, respectively, and are deposited to fill the concave portions 5a and 105a, respectively, using, for example, a low-pressure CVD method, and then etch-back processing is performed to align a top surface.

The tungsten films 9 and 109 are formed on the top surfaces of the polysilicon films 8 and 108 as metal films, respectively. The tungsten films 9 and 109 may be simultaneously formed. Subsequently, the silicon nitride films 10 and 110 are formed on the top surfaces of the tungsten films 9 and 109, respectively, and then gate processing is performed in the memory cell region, thereby forming the gate electrode MG.

The processing of the gate electrode MG in the memory cell region is performed by patterning a resist mask (not illustrated) on the silicon nitride film 10, performing dry etching under an anisotropic condition using the resist mask as a mask, and separating the stacked structures 5 to 10 from each other. The side surface of the selection gate electrode SGD (and SGS) on the gate electrode MG side is also processed through the processing. Meanwhile, in this manufacturing step, the peripheral circuit region is masked, and thus is not subjected to processing (see FIG. 5C). Subsequently, a silicon oxide film is formed as the protective films 12 and 112 using, for example, an LPCVD method. The protective film 12 in the memory cell region is formed along the side surfaces of the stacked structures 5 to 10 after the separation, is formed along the top surface of the gate insulating film 4 after the separation, and is formed along the top surface of the silicon nitride film 10. The protective film 112 in the peripheral circuit region is formed along the top surface of the silicon nitride film 110.

Subsequently, for example, n-type impurities are ion-implanted into the surface of the semiconductor substrate 2 between the gate electrodes MG and between the gate electrodes SGD and MG by an ion implantation method. The impurities are formed as the source and drain region 2a by heat treatment.

Next, the insulating films 13 and 113 are formed over the entire surface. The insulating films 13 and 113 may be formed of, for example, a silicon oxide film, and are simultaneously formed in the memory cell region and the peripheral circuit region by, for example, a plasma CVD method using a poor coatability condition. In this case, the insulating films 13 and 113 may be formed in a plurality of layers in a plurality of steps by changing film formation gas conditions.

In order to increase integration, an interval between the gate electrodes MG of the memory cells MT and an interval between the gate electrode SGD of the selection transistor STD and the gate electrode MG of the memory cell MT are small. For this reason, the insulating film 13 is not likely to be embedded between the gate electrodes MG and SGD and between the gate electrodes MG and MG, and thus the insulating film 13 is formed to cover the regions between the gate electrodes MG and SGD and between the gate electrodes MG and MG. As a result, the gap G, which is not filled with the insulating film 13, may be formed between the gate electrodes MG of the memory cells MT and between the gate electrode SGD of the selection transistor STD and the gate electrode MG of the memory cell MT. In this manner, the structures illustrated in FIGS. 5A to 5C may be formed.

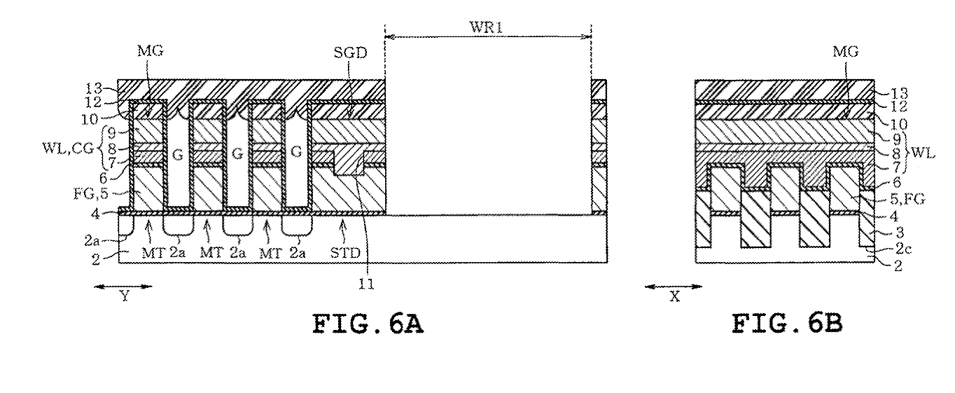

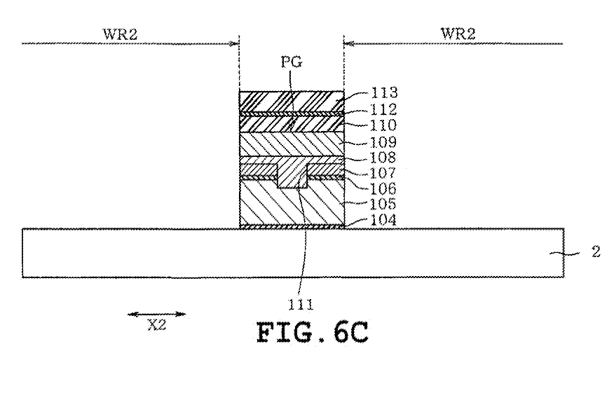

Subsequently, as illustrated in FIGS. 6A and 6B, a resist mask (not illustrated) is patterned on the insulating film 13 by a lithography method, and anisotropic etching is performed on the stacked structures 4 to 10 in a region WR1 (also see FIG. 2) where the bit line contact electrode CB (a source line contact electrode CS is also included) is formed, by an RIE method using the resist mask as a mask. Thus, the surface of the semiconductor substrate 2 within the region WR1 is exposed.

In addition, as illustrated in FIG. 6C, a resist mask (not illustrated) is patterned on the insulating film 113 by a lithography method, and anisotropic etching is performed on the stacked structures 104 to 113 in a region WR2 on either side of the gate electrode PG in the peripheral circuit region in the X2 direction, by the RIE method using the resist mask as a mask. Thus, the surface of the semiconductor substrate 2 of the gate electrode PG in the X2 direction is exposed. At this time, a region where the memory cell MT is formed and regions where the selection gate electrodes SGD and SGS are formed are masked by the resist mask, and thus are not processed.

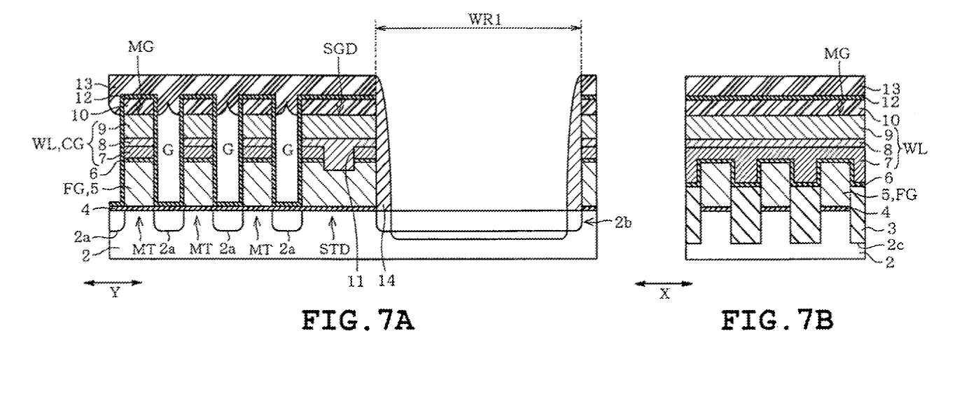

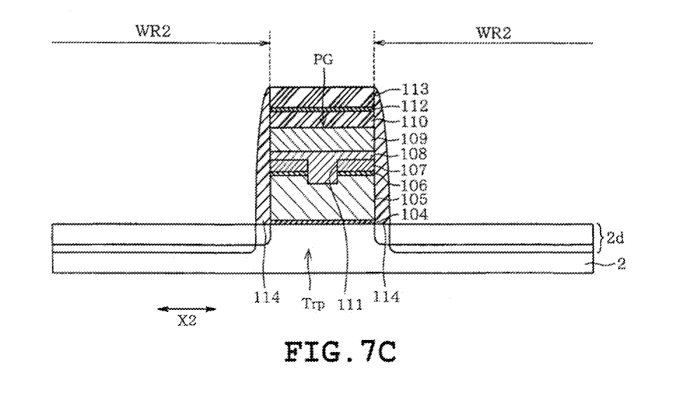

Next, as illustrated in FIGS. 7A to 7C, for example, n-type impurities are ion-implanted at a low concentration by an ion implantation method, and impurities are introduced into the surface layer of the semiconductor substrate 2 in the regions WR1 and WR2. Further, the spacer films 14 and 114 are formed. The spacer films 14 and 114 are formed by depositing, for example, a TEOS gas on the entire surface using an LPCVD method to have a uniform film thickness and then performing etch-back processing on the entire surface. The spacer films 14 and 114 may be simultaneously formed in the memory cell region and the peripheral circuit region.

As a result, as illustrated in FIG. 7A, the spacer film 14 is formed along the side surface of the structure in which the gate insulating film 4, the selection gate electrode SGD, the silicon nitride film 10, the protective film 12, and the insulating film 13 are stacked. As illustrated in FIG. 7C, the spacer film 114 is formed along the side surface of the structure in which the gate insulating film 104, the gate electrode PG, the silicon nitride film 110, the protective film 112, and the insulating film 113 are stacked in the region WR2 on either side of the gate electrodes PG. Further, for example, n-type impurities are ion-implanted at a high concentration by an ion implantation method, and impurities are introduced into the regions WR1 and WR2 except for the regions where the spacer films 14 and 114 are formed.

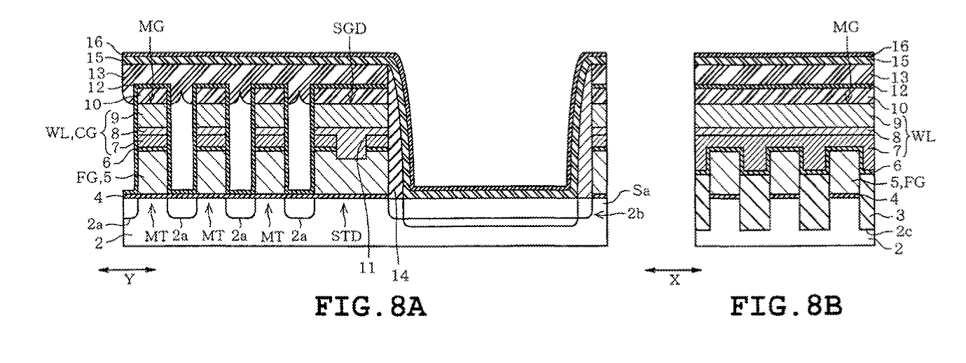

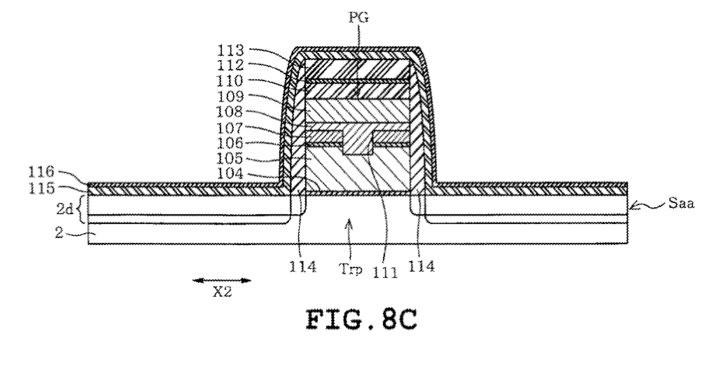

As illustrated in FIGS. 8A to 8C, the silicon oxide films 15 and 115 are formed on the entire surface as first liner films, and silicon nitride films 16 and 116 are formed on the entire surface as second liner films. The silicon oxide films 15 and 115 may be simultaneously formed using, for example, a CVD method. As illustrated in FIGS. 8A and 8B, the silicon oxide film 15 in the memory cell region is formed along the top surface of the element region Sa of the semiconductor substrate 2, the side surface and the top surface of the spacer film 14, and the top surface of the insulating film 13. As illustrated in FIG. 8C, the silicon oxide film 115 in the peripheral circuit region is formed along the top surface of the element region Saa of the semiconductor substrate 2, the side surface and the top surface of the spacer film 114, and the top surface of the insulating film 113.

The silicon nitride films 16 and 116 may be simultaneously formed using, for example, a CVD method. As illustrated in FIGS. 8A and 8B, the silicon nitride film 16 is formed on the silicon oxide film 15. As illustrated in FIG. 8C, the silicon nitride film 116 is formed on the silicon oxide film 115.

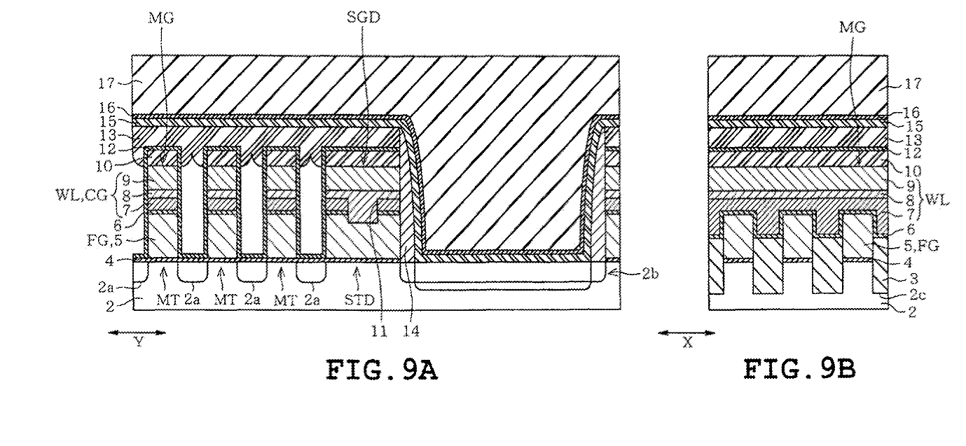

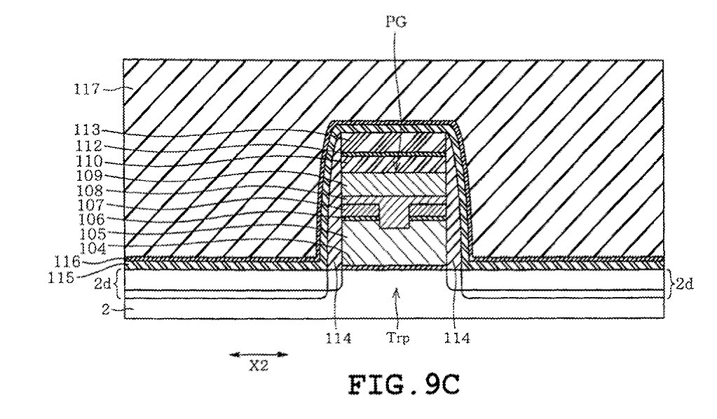

As illustrated in FIGS. 9A to 9C, the interlayer insulating films 17 and 117 are formed on the silicon nitride films 16 and 116, respectively. The interlayer insulating films 17 and 117 may be simultaneously formed of a silicon oxide film using, for example, a CVD method. At this point in time, the top surfaces of the interlayer insulating films 17 and 117 may also be planarized using, for example, a CMP method.

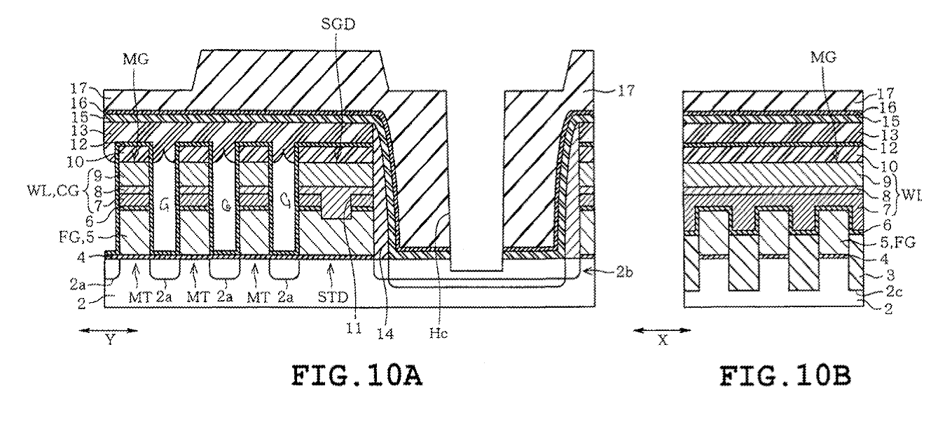

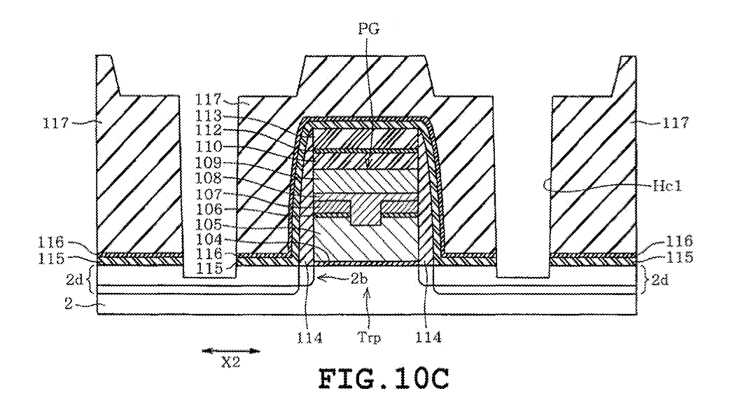

As illustrated in FIGS. 10A to 10C, a resist mask (not illustrated) is formed on the interlayer insulating films 17 and 117, and patterning is performed to form an opening at a location corresponding to each of the contact electrodes CB, CP1, and CP2 within the regions WR1 and WR2. Next, the hole Hc is formed in the interlayer insulating films 17 and 117 using the silicon nitride films 16 and 116 as stoppers. Thereafter, the hole Hc is formed to reach the semiconductor substrate 2. At this time, the hole Hc of the bit line contact electrode CB (the source line contact electrode CS is also included) and the hole Hc1 for burying the contact electrodes CP1 and CP2 are simultaneously formed. Meanwhile, a method of forming the holes Hc and Hc1 includes a method of individually forming an upper hole having a large diameter and a lower hole having a small diameter.

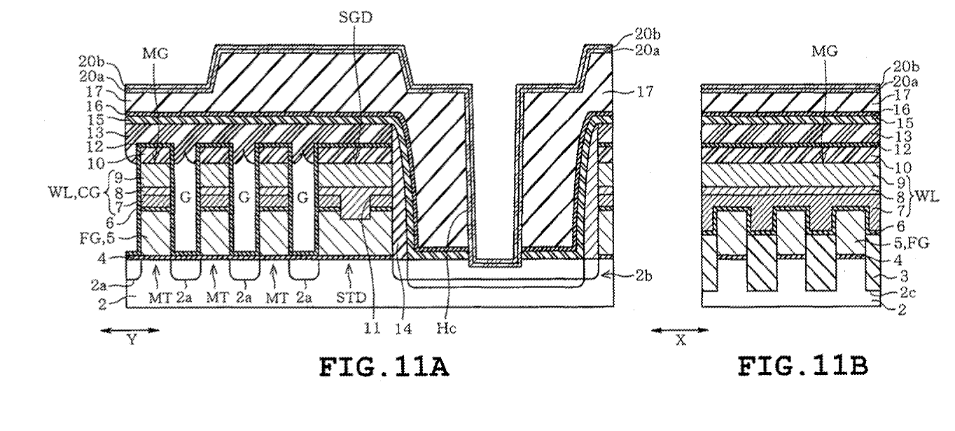

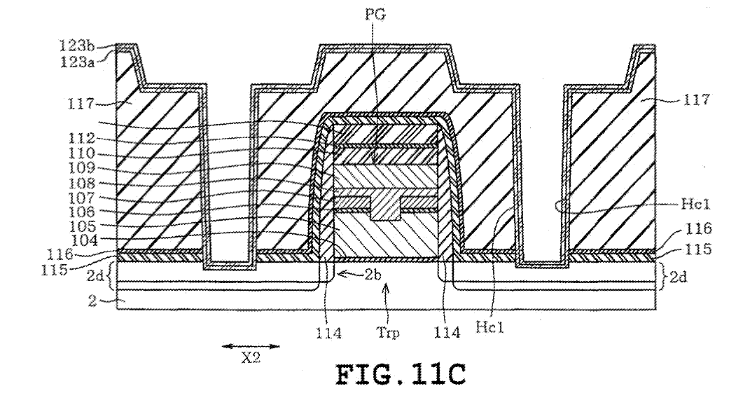

Subsequently, as illustrated in FIGS. 11A to 11C, an amorphous silicon film 20a is formed along the inner surface of the hole Hc, and an amorphous silicon film 123a is formed along the inner surface of the hole Hc1. At this time, the amorphous silicon films 20a and 123a may be simultaneously formed using, for example, a CVD method.

Subsequently, for example, titanium (Ti) films serving as barrier metal films 20b and 123b are formed on the amorphous silicon films 20a and 123a. The barrier metal films 20b and 123b may be simultaneously formed using, for example, a CVD method.

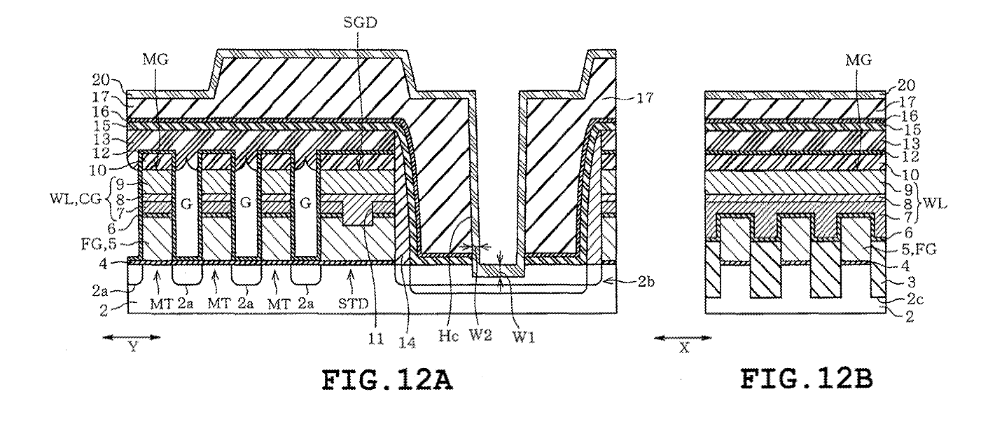

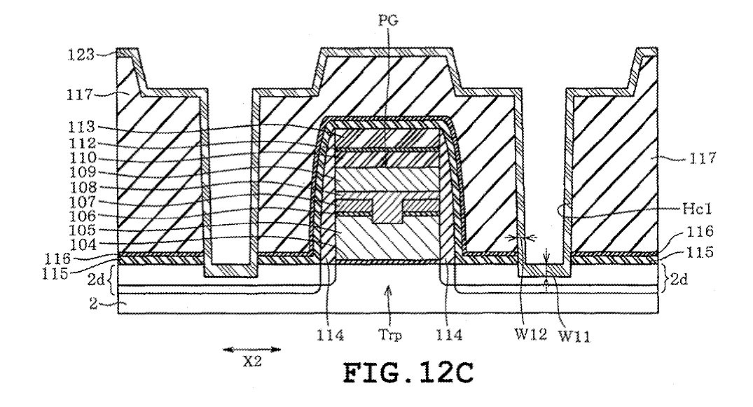

Subsequently, as illustrated in FIGS. 12A to 12C, a siliciding reaction is caused between the barrier metal films 20b and 123b and the amorphous silicon films 20a and 123a by performing heat treatment using, for example, a diffusion furnace or an RTP under a temperature condition of 600° C. or higher to thereby form the metal silicide films 20 and 123. At this time, the metal silicide films 20 and 123 remain along the inner surfaces of the holes Hc and Hc1 as titanium silicide films.

For example, when the silicon oxide (SiO) and a barrier metal in the interlayer insulating films 17 and 117 directly come into contact with each other, the barrier metal corrodes due to a —OH group (hydroxy group) remaining in SiO during film formation, which results in a possibility of defects occurring. However, according to this embodiment, it is possible to significantly prevent titanium (Ti) used as the barrier metal from directly coming into contact with the silicon oxide film configuring the interlayer insulating films 17 and 117 and to prevent defects from occurring due to the corrosion of the barrier metal. In particular, the amorphous silicon films 20a and 123a are formed, and the barrier metal is formed, and then silicidation occurs. Accordingly, the barrier metal does not directly come into contact with the interlayer insulating films 17 and 117.

In this manufacturing step, the holes Hc and Hc1 penetrate up to the semiconductor substrate 2. For this reason, when the semiconductor substrate 2 is formed of a single crystal silicon substrate, the silicidation of the barrier metal is stopped at an interface between the holes Hc and Hc1 and the interlayer insulating films 17 and 117 on the side surfaces of the holes Hc and Hc1, but the silicon substrate is present on the bottom surfaces of the holes Hc and Hc1, and thus the silicidation of the barrier metal further proceeds. Therefore, when this heat treatment process is performed, the silicidation film thicknesses W1 and W11 of the respective metal silicide films 23 and 123 of the bottom surfaces of the holes Hc and Hc1 are larger than the silicidation film thicknesses W2 and W12 of the side surfaces thereof.

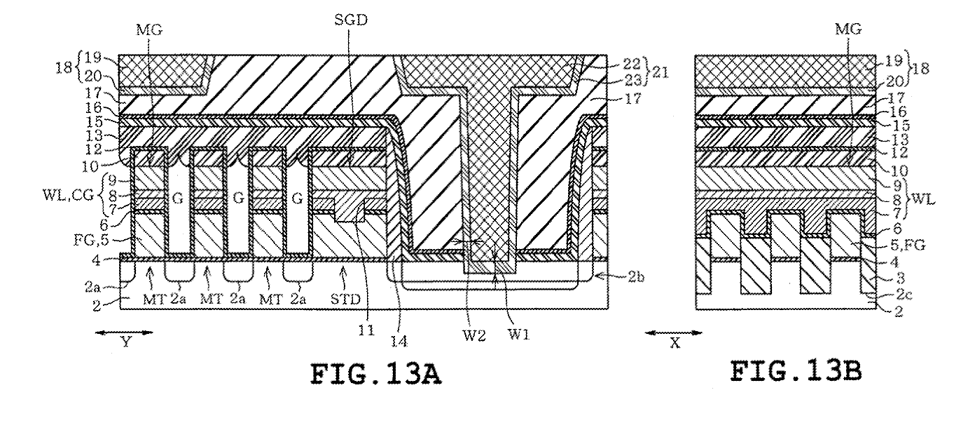

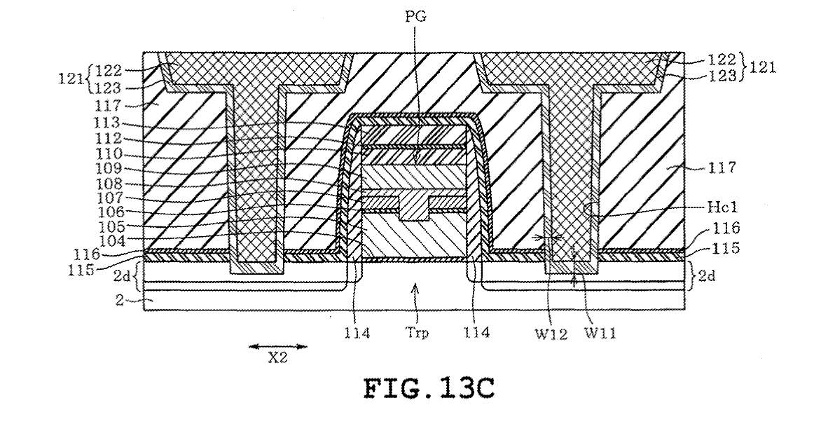

As illustrated in FIGS. 13A to 13C, the wiring layers 19, 22, and 122 are embedded within the respective metal silicide films 20, 23, and 123. At this time, the wiring layers 19, 22, and 122 are formed of, for example, tungsten and may be simultaneously formed using, for example, a CVD method. In addition, the wiring layers may be formed using a PVD method. At this time, the wiring layers 19, 22, and 122 may be embedded within both the lower hole and the upper hole. Then, the wiring layers 19, 22, and 122 are planarized by a CMP method by using the top surfaces of the interlayer insulating films 17 and 117 as stoppers. Thus, it is possible to form the wiring portions 18, 21, and 121 with high reliability by using a so-called dual damascene method.

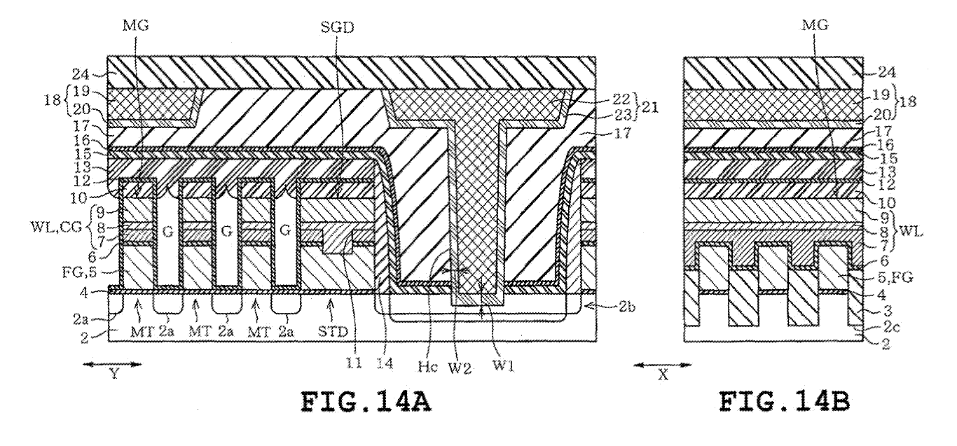

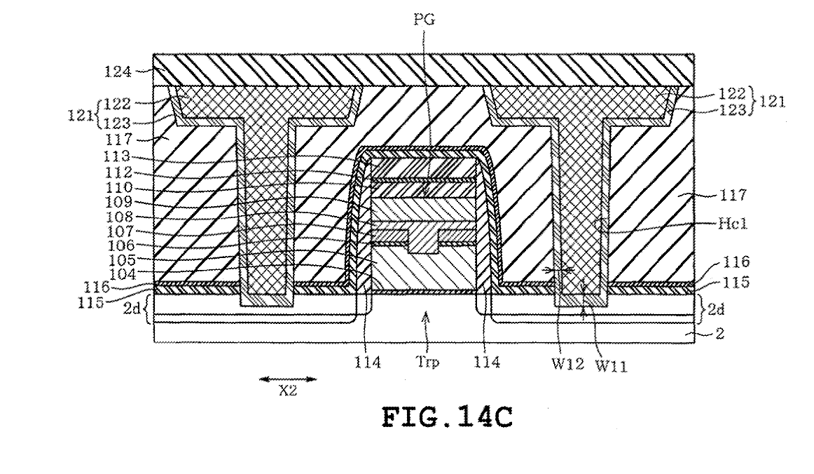

As illustrated in FIGS. 14A to 14C, the interlayer insulating films 24 and 124 are formed on the wiring portions 18, 21, and 121 and the interlayer insulating films 17 and 117. The interlayer insulating films 24 and 124 are formed of, for example, a silicon oxide film and may be simultaneously formed using, for example, a CVD method.

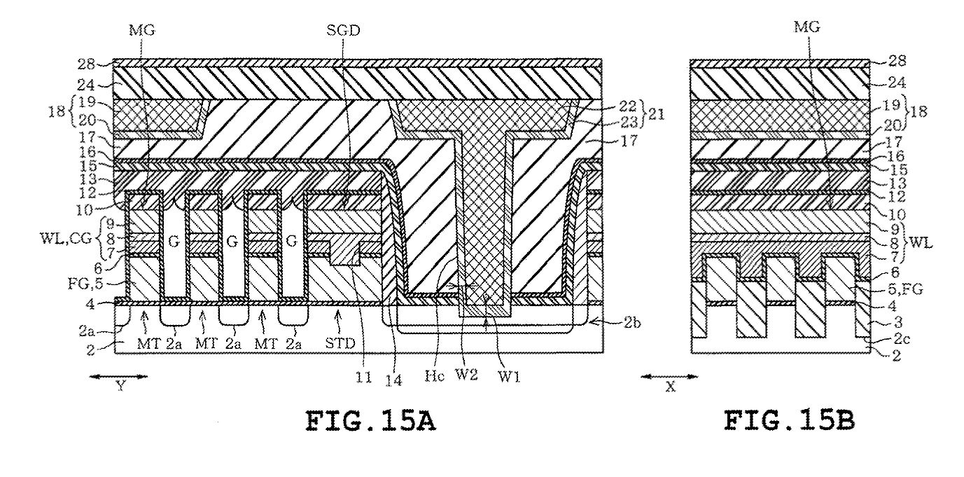

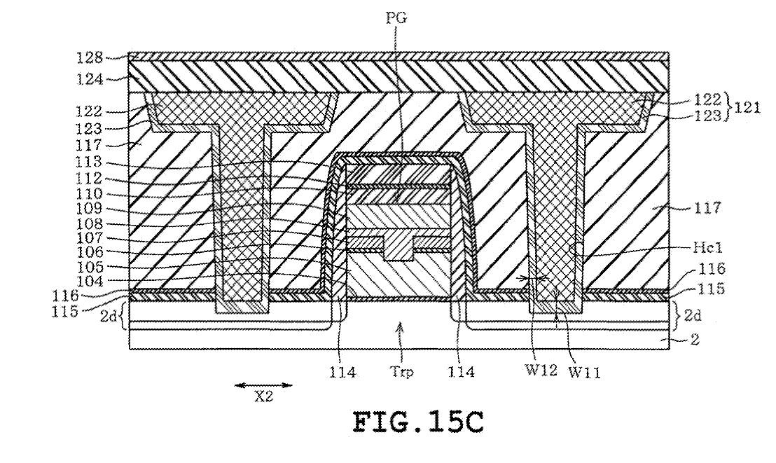

As illustrated in FIGS. 15A to 15C, the barrier films 28 and 128 are formed. The barrier films 28 and 128 may be simultaneously formed of, for example, a silicon nitride film by using, for example, a CVD method.

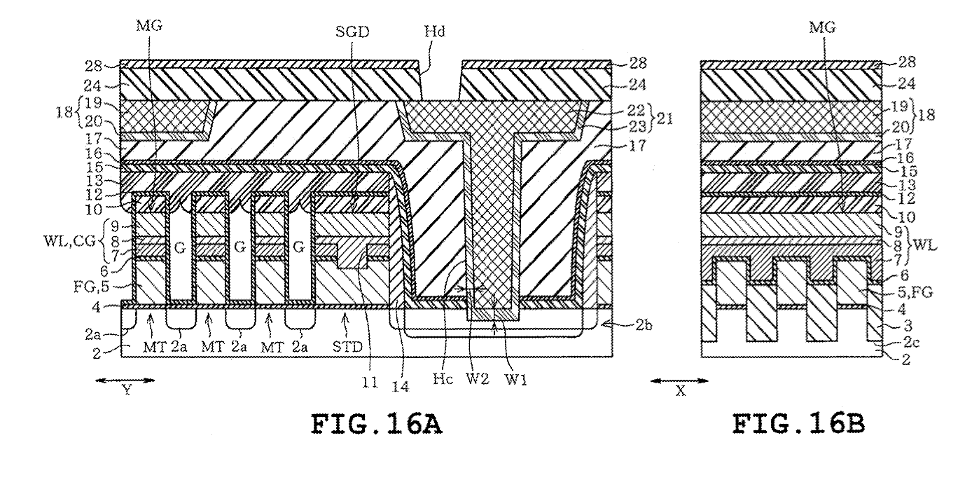

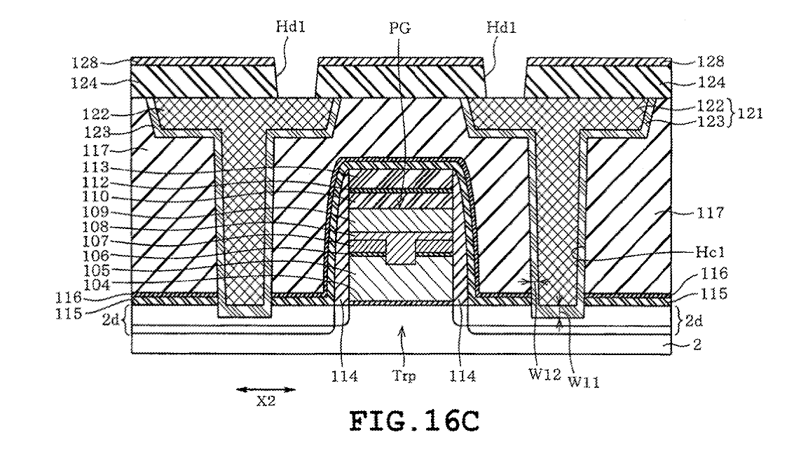

As illustrated in FIGS. 16A to 16C, a resist pattern (not illustrated) is formed on the barrier films 28 and 128 using a photolithography method, anisotropic etching is performed by an RIE method using the resist pattern as a mask, and the holes Hd and Hd1 are formed through the barrier films 28 and 128 and the interlayer insulating films 24 and 124 to reach the top portions of the wiring portions 18, 21, and 121. The holes Hd and Hd1 may be simultaneously formed in this manufacturing step.

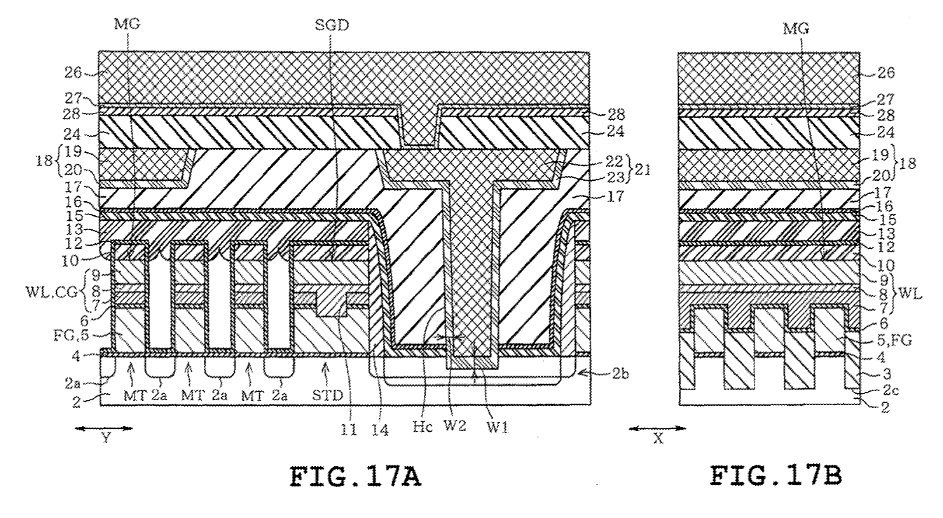

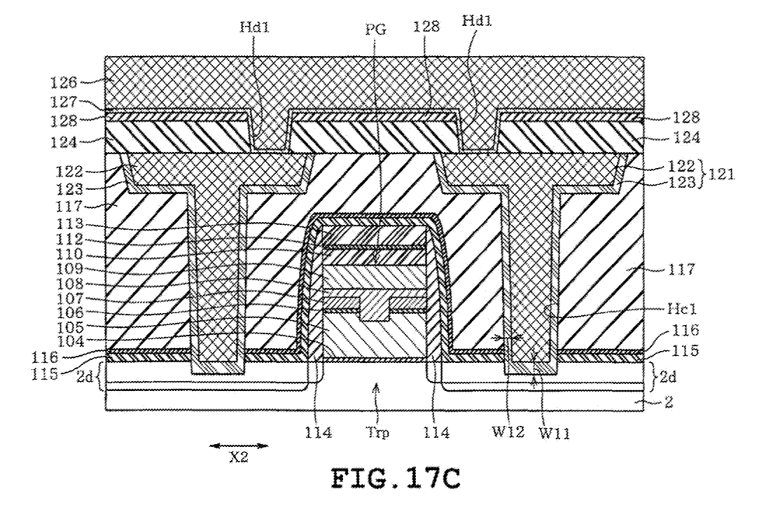

As illustrated in FIGS. 17A to 17C, for example, the barrier metal films 27 and 127 are formed, and the wiring layers 26 and 126 are embedded on the barrier metal films 27 and 127. The barrier metal films 27 and 127 are formed of, for example, titanium nitride (TiN) and may be simultaneously formed using, for example, a PVD method. In addition, the wiring layers 26 and 126 are formed of a metal such as, for example, tungsten (W), and thus may be simultaneously formed using, for example, a CVD method. Meanwhile, the wiring layers 26 and 126 may be formed by a PVD method. Subsequently, planarization is performed using a CMP method by causing the barrier films 28 and 128 to function as stoppers, and thus the barrier metal films 27 and 127 and the wiring layers 26 and 126 on the barrier films 28 and 128 are removed. Thus, the wiring portions 25 and 125 may be formed.

As illustrated in FIGS. 4A to 4C, the interlayer insulating films 29 and 129 are formed on the barrier films 28 and 128 and the wiring portions 25 and 125. The interlayer insulating films 29 and 129 are formed of, for example, a silicon oxide film and may be simultaneously formed using, for example, a CVD method.

Subsequently, the interlayer insulating films 29 and 129 are planarized, patterning is performed on the interlayer insulating films 29 and 129 by applying a resist (not illustrated) thereto, and a groove is formed in a region where the bit line BL is to be formed, by anisotropic etching using an RIE method by using the resist mask (not illustrated) as a mask. The plurality of grooves are formed to extend in the Y direction in the memory cell region illustrated in FIGS. 4A and 4B to be spaced from one another in the X direction. The depth of the groove is adjusted to a depth exceeding a total thickness of the interlayer insulating films 29 and 129 and the barrier films 28 and 128 by adjusting an etching time. Then, a conductive material is embedded within the groove so that the bit line BL is formed in the memory cell region and the wiring portion 130 is formed in the peripheral circuit region. The bit lines BL formed of, for example, copper (Cu) or tungsten (W) may be simultaneously formed using, for example, a CVD method. In this manner, the structures illustrated in FIGS. 4A to 4C may be manufactured. Further, an upper layer wiring is formed on the bit lines BL and the wiring portion 130, but a description thereof will be omitted. In this manner, the nonvolatile semiconductor memory device 1 may be manufactured.

According to the first embodiment, the metal silicide films 20 and 23 are formed between the interlayer insulating film 17 and the respective wiring layers 19 and 22, and the metal silicide film 123 is formed between the wiring layer 122 and the interlayer insulating film 117. Accordingly, even when a barrier metal film material is formed between the metal film and the interlayer insulating film, it is possible to improve corrosion resistance of the material. Thus, it is possible to improve the long term reliability of the wiring portion 18, the bit line contact electrode CB (the source line contact electrode CS is also included), and the contact electrodes CP1 and CP2.

### Second Embodiment

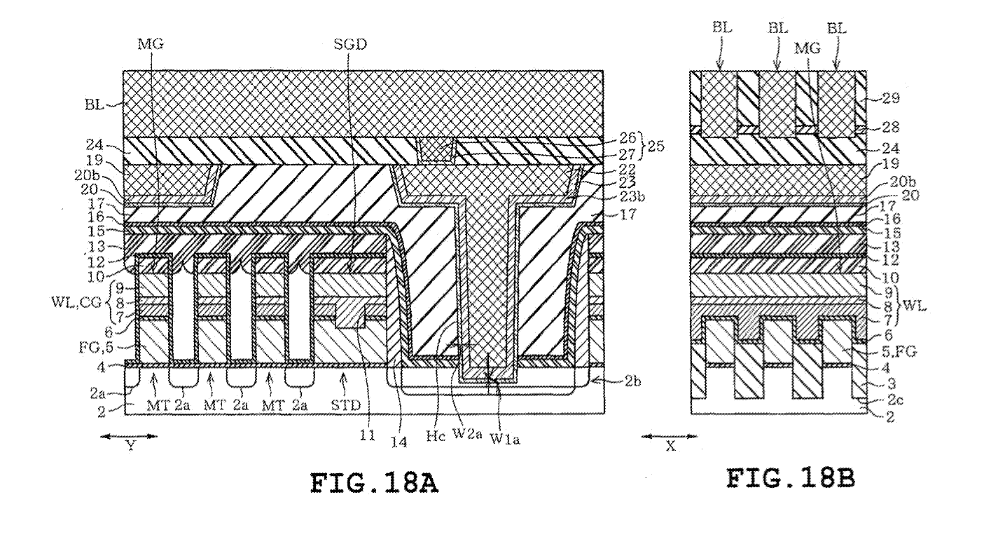

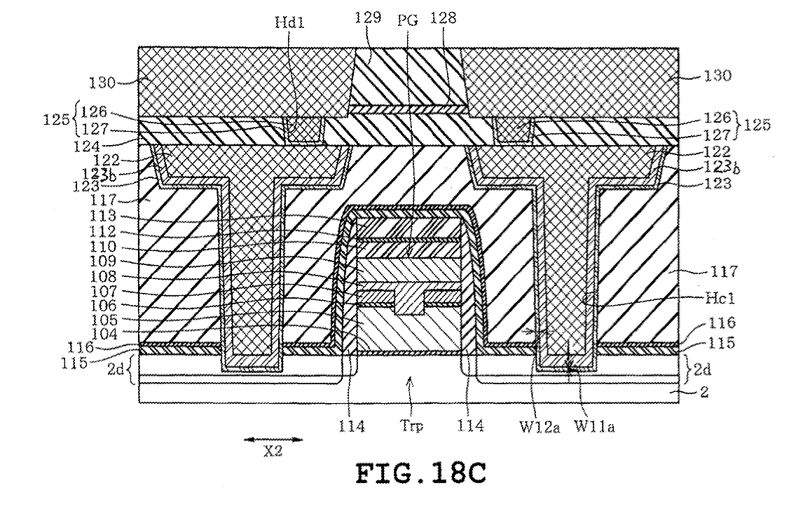

FIGS. 18A to 18C illustrate a second embodiment. FIG. 18A is an example of a schematic cross-sectional view taken along line 4A-4A of FIG. 2, and FIG. 18B is an example of a schematic cross-sectional view taken along line 4B-4B of FIG. 2. In addition, FIG. 18C is an example of a schematic cross-sectional view taken along line 4C-4C of FIG. 3.

According to the second embodiment, in a manufacturing step of forming the amorphous silicon films 20a, 23a, and 123a or the barrier metal film according to the first embodiment, the amorphous silicon films 20a, 23a, and 123a are formed to have a small film thickness, or the barrier metal films 20b and 123b are formed to have a large film thickness, as compared with the first embodiment.

Accordingly, when the metal silicide films 20, 23, and 123 are formed by forming the amorphous silicon films 20a, 23a, and 123a, forming titanium films serving as the barrier metal films 20b and 123b, and then performing heat treatment, the barrier metal film 20b may remain within the metal silicide film 20, the barrier metal film 23b may remain within the metal silicide film 23, and the barrier metal film 123b may remain within the metal silicide film 123, as illustrated in FIGS. 18A to 18C.

Meanwhile, when the semiconductor substrate 2 is a single crystal silicon substrate, the metal silicide film 23 in the memory cell region is configured such that thickness W1a of a portion of the silicide film coming into contact with the semiconductor substrate 2 is larger than a silicidation film thickness W2a of a side surface coming into contact with the interlayer insulating film 17. The same is true of the metal silicide film 123 in the peripheral circuit region. The metal silicide film 123 is configured such that a silicidation film thickness W11a of a portion coming into contact with the semiconductor substrate 2 is larger than a silicidation film thickness W12a of a side surface coming into contact with the interlayer insulating film 117.

Also in the second embodiment, the same operational effects as the first embodiment are exhibited.

### Third Embodiment

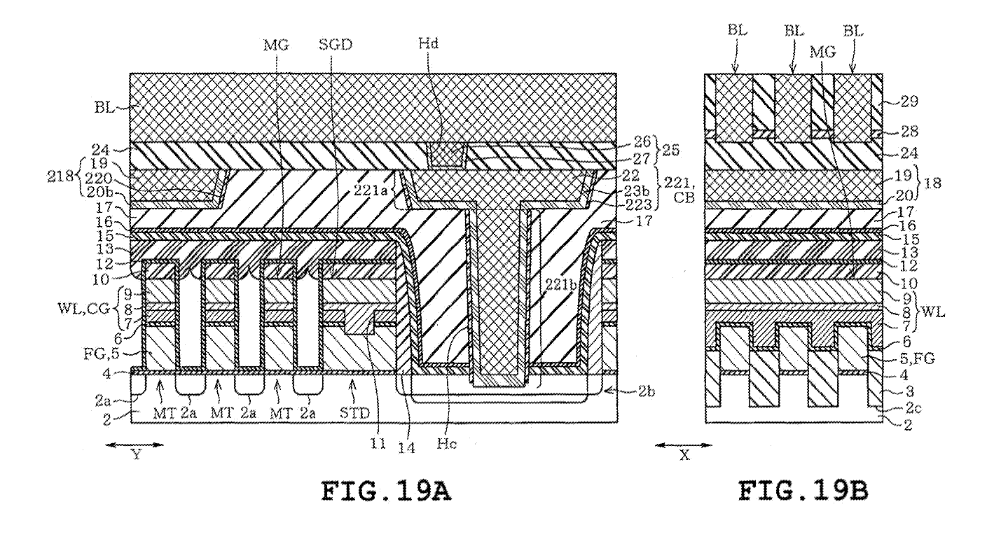

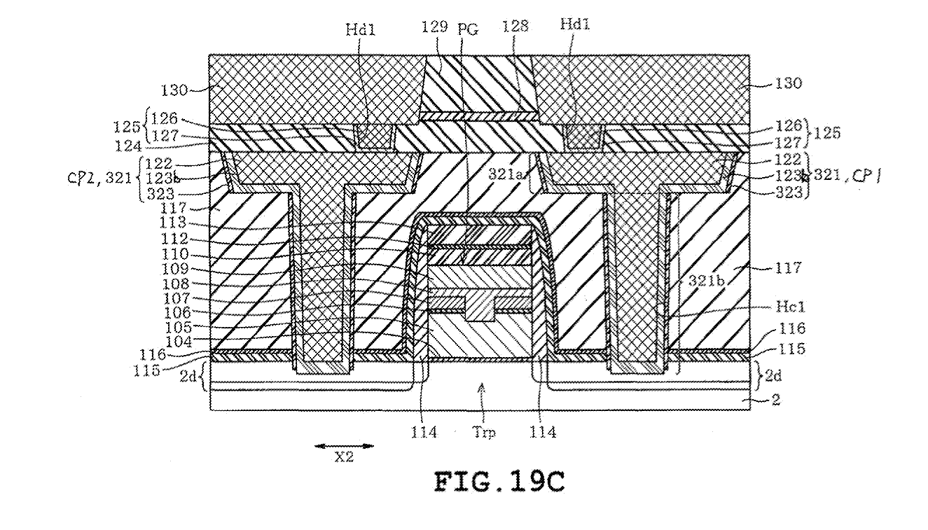

FIGS. 19A to 19C to FIGS. 21A to 21C illustrate a third embodiment. FIG. 19A is an example of a schematic cross-sectional view taken along line 4A-4A of FIG. 2, and FIG. 19B is an example of a schematic cross-sectional view taken along line 4B-4B of FIG. 2. In addition, FIG. 19C is an example of a schematic cross-sectional view taken along line 4C-4C of FIG. 3.

In the third embodiment, a configuration is illustrated in which first films 220, 223, and 323 including a silicon nitride (dielectric body) are formed instead of the metal silicide films 20, 23, and 123 according to the first embodiment.

As illustrated in FIG. 19A, a wiring layer 218 is formed in an interlayer insulating film 17 over memory cells MT. The wiring layer 218 includes the first film 220 including a silicon nitride film, a barrier metal film 20b, and a wiring layer 19. The first film 220 is a film including a silicon nitride (silicon nitride film) and is configured as a dielectric film. Meanwhile, the first film 220 may be formed of a silicon nitrocarbide film. The first film 220 is formed between the inner surface of the interlayer insulating film 17 and the side surface of the barrier metal film 20b.

As illustrated in FIG. 19A, the wiring layer 221 is located on a semiconductor substrate 2 and is configured to include a bit line contact electrode CB. A description will be given below based on a shape. The wiring layer 221 includes a wiring portion 221a, having a large width, which is formed to have the same height as that of the wiring layer 218 and is formed in the same layer as the wiring layer 218, and a contact portion 221b, having a small width, which connects a portion of the lower portion of the wiring portion 221a and an upper portion of the semiconductor substrate 2.

In addition, the wiring portion 221a is formed to be located above the memory cells MT. In addition, a description will be given below based on a film forming material. The wiring portion 221a includes a wiring layer 22 including a metal, a barrier metal film 23b, and the first film 223 which is formed along the side surface of the barrier metal film 23b. The first film 223 is an insulating film including a silicon nitride (silicon nitride film) and is configured as a dielectric film. Meanwhile, the first film 223 may be formed of a silicon nitrocarbide film.

The first film 223 is formed between the interlayer insulating film 17 and the side surface of a barrier metal film 22b within the wiring portion 221a. In addition, the first film 223 is formed between the interlayer insulating film 17 and the side surface of barrier metal film 23b of the contact portion 221b. Meanwhile, as illustrated in FIG. 19A, the first film 223 is formed to slightly come into contact with the semiconductor substrate 2, but the contact portion may be a portion instead of the whole surface.

In addition, as illustrated in FIG. 19C, a wiring layer 321 is configured as contact electrodes CP1 and CP2 located on the semiconductor substrate 2. A description will be given below based on a shape. The wiring layer 321 includes a wiring portion 321a, having a large width, which is formed to have the same height as those of the wiring layers 218 and 221a and is formed in the same layer as the wiring layers, and a contact portion 321b, having a smaller width, which connects a portion of a lower portion of the wiring portion 321a and the upper portion of the semiconductor substrate 2. In addition, the wiring portion 321a is formed to be located above a gate electrode PG.

In addition, a description will be given below based on a film forming material. The wiring layer 321 includes a wiring layer 122 including a metal, a barrier metal film 123b formed along the bottom surface and side surface of the wiring layer 122, and the first film 323 formed along the outer side surface of the barrier metal film 123b. The first film 323 is an insulating film including a silicon nitride (silicon nitride film), and is configured as a dielectric film. Meanwhile, the first film 323 may be formed of a silicon nitrocarbide film. In this manner, the first films 223 and 323 are not formed in at least a part of the portion coming into contact with the semiconductor substrate 2 and are formed in portions coming into contact with the respective interlayer insulating films 17 and 117.

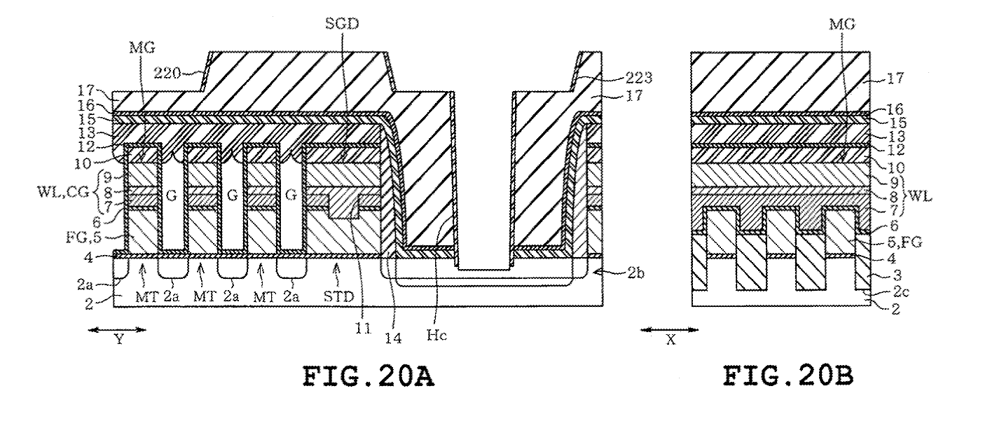

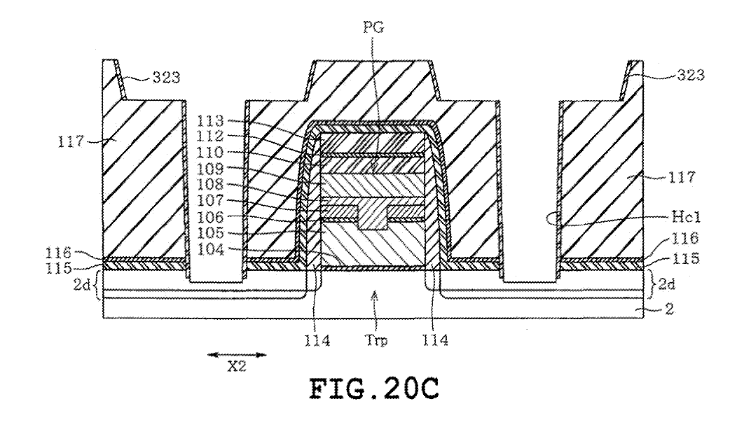

A method of manufacturing the above-mentioned structure will be schematically described below. First, the structures up to the manufacturing steps illustrated in FIGS. 10A to 10C are formed using the manufacturing method described in the first embodiment. Subsequently, as illustrated in FIGS. 20A to 20C, the first films 220, 223, and 323 are formed. When the first films 220, 223, and 323 are formed of, for example, a silicon nitride film, and the films may be simultaneously formed using, for example, a CVD method. Then, anisotropic etching is selectively performed on the first films 220, 223, and 323 using an RIE method. As a result, as illustrated in FIGS. 20A to 20C, it is possible to leave the first films 220, 223, and 323 along the inner surfaces of the holes.

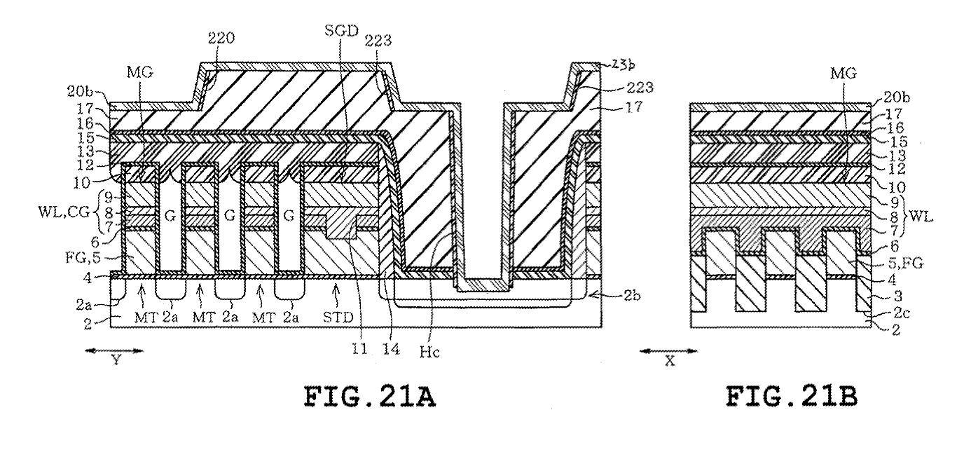

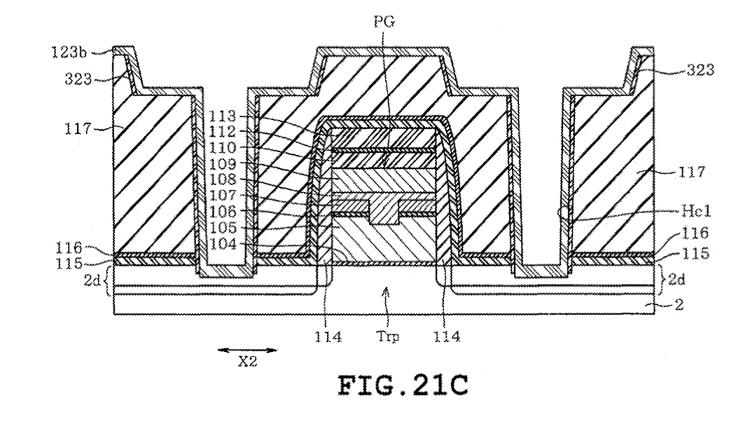

Thereafter, as illustrated in FIGS. 21A to 21C, the barrier metal films 20b, 23b, and 123b are isotropically formed. Meanwhile, in the manufacturing step of FIG. 21A, the barrier metal films 20b and 23b are formed integrally, but are illustrated in FIG. 21A by being given both reference numerals 20b and 23b. The barrier metal films 20b, 23b, and 123b may be simultaneously formed using the same method as the method described in the first embodiment. Thereafter, the wiring layers 19, 22, and 122 are embedded. The wiring layers 19, 22, and 122 may also be simultaneously formed using the same method as the method described in the first embodiment. The subsequent manufacturing processes are the same as those in the first embodiment, and thus a description thereof will be omitted.

Also in the third embodiment, it is possible to prevent portions of the first films 220, 223, and 323 formed between the interlayer insulating films 17 and 117 and the barrier metal films 20b, 23b, and 123b from corroding as much as possible.

### Fourth Embodiment

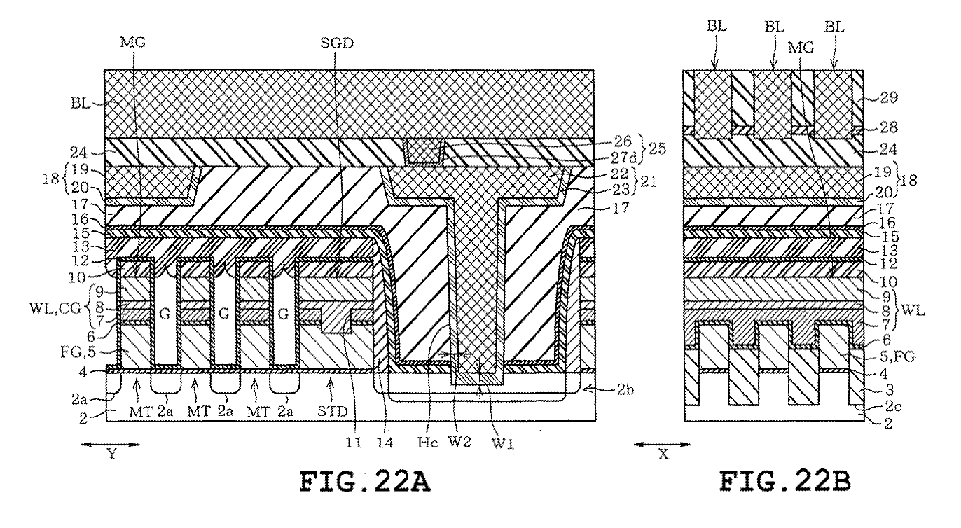

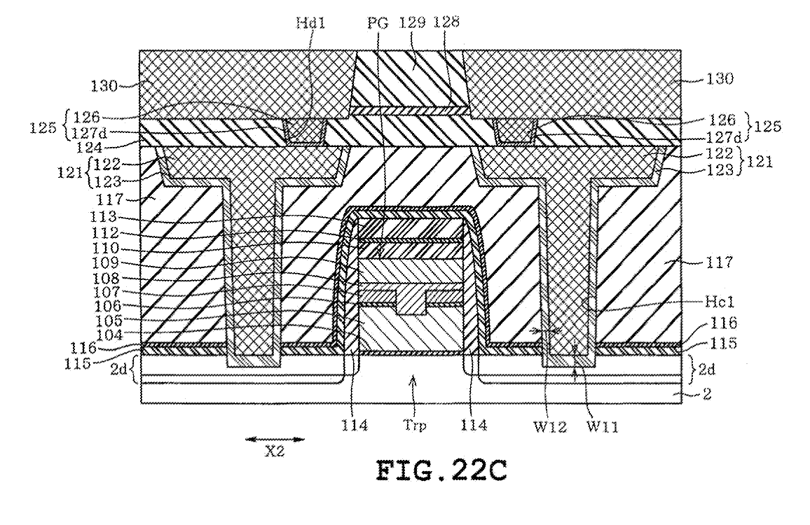

FIGS. 22A to 22C illustrate a fourth embodiment. FIG. 22A is an example of a schematic cross-sectional view taken along line 4A-4A of FIG. 2, and FIG. 22B is an example of a schematic cross-sectional view taken along line 4B-4B of FIG. 2. In addition, FIG. 22C is an example of a schematic cross-sectional view taken along line 4C-4C of FIG. 3.

In the first embodiment, a configuration is illustrated in which the barrier metal films 27 and 127 in the respective interlayer insulating films 24 and 124 directly come into contact with the interlayer insulating films 24 and 124, respectively. However, as illustrated in FIGS. 22A to 22C, metal silicide films 27d and 127d may be formed instead of the barrier metal films 27 and 127. A method of forming the metal silicide films 27d and 127d is the same as the method of forming the metal silicide films 23 and 123 described in the first embodiment, and thus a description thereof will be omitted.

### Fifth Embodiment

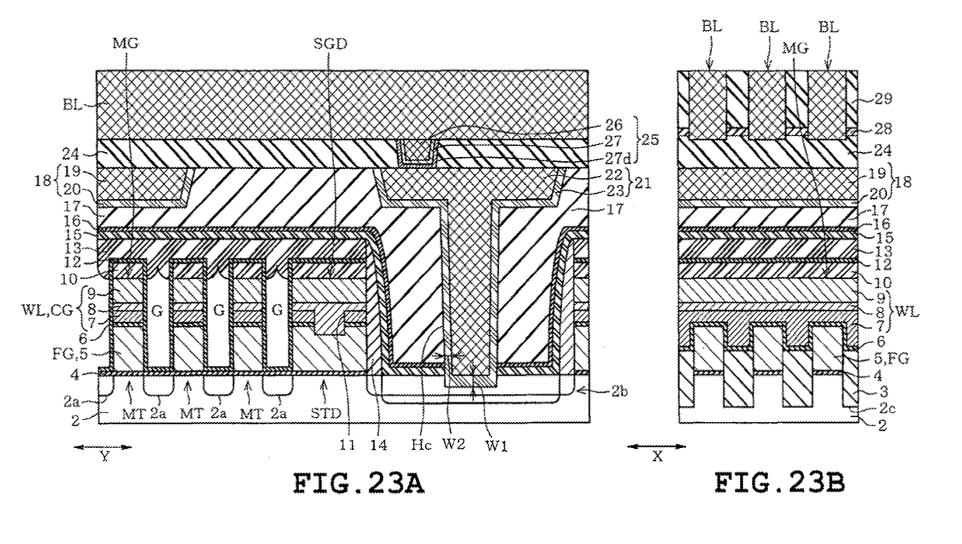

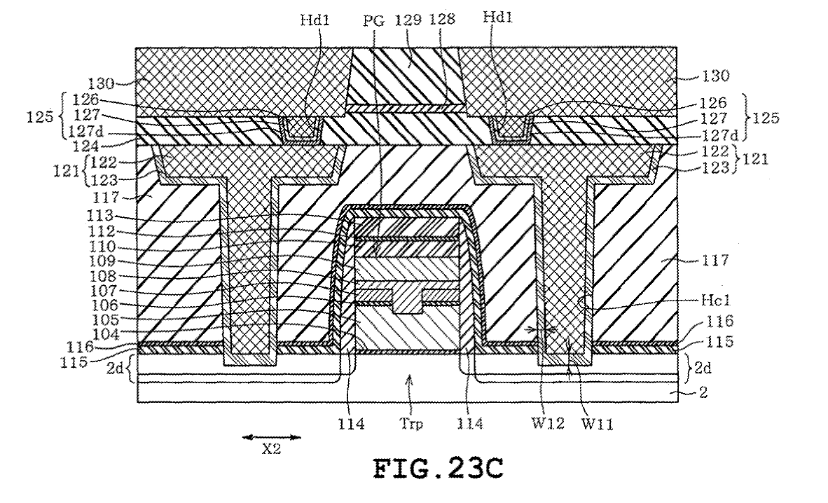

FIGS. 23A to 23C illustrate a fifth embodiment. FIG. 23A is an example of a schematic cross-sectional view taken along line 4A-4A of FIG. 2, and FIG. 23B is an example of a schematic cross-sectional view taken along line 4B-4B of FIG. 2. In addition, FIG. 23C is an example of a schematic cross-sectional view taken along line 4C-4C of FIG. 3.

In this case, as illustrated in FIG. 23A, a metal silicide film 27d may be formed between a wiring layer 21 and a wiring layer 26 as an electrode. In addition, a barrier metal film 27 may be formed between a metal silicide film 27d and the wiring layer 26. As illustrated in FIG. 23C, a metal silicide film 127d may be formed between the wiring layer 21 and the wiring layer 26 as an electrode. In addition, a barrier metal film 127 may be formed between the metal silicide film 127d and a wiring layer 126.

Although the NAND type flash memory device 1 is used, a NOR-type flash memory device or a nonvolatile semiconductor memory device such as an EEPROM may be used. Any semiconductor device may be used as long as the semiconductor device is provided with a wiring layer including a metal in an interlayer insulating film.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a semiconductor element that is formed on a semiconductor substrate;
an interlayer insulating film, including a silicon oxide film, that is formed to cover the semiconductor element;
a wiring layer, including a metal, that is formed in the interlayer insulating film; and
a first metal silicide film that is formed between the wiring layer and the interlayer insulating film.

2. The semiconductor device according to claim 1, further comprising:
a first barrier metal film throughout an entire surface between the first metal silicide film and the wiring layer.

3. The semiconductor device according to claim 1,
wherein the wiring layer is configured such that a wiring portion formed throughout an upper side of the semiconductor element and a contact portion that connects the semiconductor substrate and a portion of a lower portion of the wiring portion, are integrally formed, and
wherein the first metal silicide film is continuously formed on a bottom surface and a side surface of the wiring portion and a bottom surface and a side surface of the contact portion that is formed integrally with the wiring portion.

4. The semiconductor device according to claim 1,
wherein the semiconductor substrate is formed of a silicon substrate, and
wherein the metal silicide film is configured such that a first film thickness of a portion coming into contact with the silicon substrate is larger than a second film thickness of a portion coming into contact with the interlayer insulating film.

5. The semiconductor device according to claim 1, further comprising:
a second interlayer insulating film that is formed on the wiring layer;
an electrode that is formed on the second interlayer insulating film and is formed on the wiring layer;
a second metal silicide film that is formed between the wiring layer and the electrode and between the electrode and the second interlayer insulating film; and
a second barrier metal film that is formed between the second metal silicide film and the electrode.

6. The semiconductor device according to claim 1,
wherein the wiring layer is formed throughout an upper side of the semiconductor element, and
wherein the first metal silicide film is formed on the entirety of a side surface and a bottom surface of the wiring portion.

7. The semiconductor device according to claim 1,
wherein the semiconductor element has a configuration in which memory cells are connected to each other in series, the memory cells each of which is configured such that a gate insulating film, a charge storage layer, a first insulating film, and a control electrode are stacked on the semiconductor substrate.

8. A semiconductor device comprising:
a semiconductor element;
an interlayer insulating film, including a silicon oxide film, that is formed to cover the semiconductor element;
a wiring layer, including a metal, that is formed in the interlayer insulating film;
a first barrier metal film that is formed between the wiring layer and the silicon oxide film of the interlayer insulating film; and
a first film, including a silicon nitride, that is formed between the first barrier metal film and the silicon oxide film of the interlayer insulating film.

9. The semiconductor device according to claim 8,
wherein the first barrier metal film is formed throughout an entire surface between the wiring layer and the first film.

10. The semiconductor device according to claim 8,
wherein the wiring layer is configured such that a wiring portion formed throughout an upper side of the semiconductor element and a contact portion that connects the semiconductor substrate and a portion of a lower portion of the wiring portion, are integrally formed, and
wherein the first film is formed between the silicon oxide film of the interlayer insulating film and a bottom surface and a side surface of the wiring portion.

11. The semiconductor device according to claim 8,
wherein the first film is not formed in at least a part of a portion coming into contact with the semiconductor substrate, and is formed in a portion coming into contact with the interlayer insulating film.

12. The semiconductor device according to claim 11, further comprising:
a first barrier metal film between the wiring layer and the first film,
wherein the first barrier metal film comes into contact with the semiconductor substrate and the metal in the contact portion.

13. The semiconductor device according to claim 8,
wherein the wiring layer configures a wiring portion formed above an upper side of the semiconductor element, and
wherein the first film is formed over the entirety of a bottom surface and a lower surface of the wiring portion.

14. The semiconductor device according to claim 8,
wherein the semiconductor element has a configuration in which memory cells are connected to each other in series, the memory cells each of which is configured such that a gate insulating film, a charge storage layer, a first insulating film, and a control electrode are stacked on the semiconductor substrate.
